(19) United States
(12) Patent Application Publication
(10) Pub. No.: US 2026/0252362 A1
(43) Pub. Date: Aug. 27, 2026

(54) SYSTEM DESIGN DEVICE, SYSTEM DESIGN METHOD, AND RECORDING MEDIUM

(71) Applicant: NEC Corporation, Minato-ku, Tokyo (JP)

(72) Inventors: Toshiki WATANABE, Tokyo (JP); Takayuki KURODA, Tokyo (JP)

(73) Assignee: NEC Corporation, Minato-ku, Tokyo (JP)

(21) Appl. No.: 18/856,159

(22) PCT Filed: Apr. 28, 2022
(86) PCT No.: PCT/JP2022/019413

§ 371 Date: Oct. 11, 2024

(51) Int. Cl. G06F 9/445

(52) U.S. Cl. CPC G06F 9/44505

(57) ABSTRACT

A system design device selects one or more of configuration components of a target system configuration based on a configuration component selection method indicated in constraint condition generation information that is associated with system configuration information. The system configuration information indicates a target system configuration. The target system configuration is one of target candidates for system design in which repetitive application of a concretization rule to a system configuration including an abstract configuration component is performed. The constraint condition generation information indicates a method of generating a constraint condition for the target system configuration. The system design device generates a constraint condition for the target system configuration. The system design device determines whether or not the target system configuration can satisfy the constraint condition.

### TECHNICAL FIELD

The present invention relates to a system design device, a system design method, and a recording medium.

### BACKGROUND ART

Several techniques related to system design have been proposed.

For example, the system configuration derivation device disclosed in Patent Document 1 concretizes an abstract configuration, which is a system configuration with undetermined parts, so as to satisfy the quantitative requirements required of the system, and obtains a concrete configuration that is a system configuration free of undetermined parts.

Moreover, in a case where the system configuration derivation device disclosed in Patent Document 2 applies concretization rules to the configuration requirements of the construction target system to update the configuration requirements, it calculates a score indicating the degree of appropriateness of the concretization rule based on a calculation method obtained by machine learning, and determines the concretization rule to be applied to the configuration requirements of the construction target system based on the score.

Furthermore, Patent Document 3 discloses a client-server system configuration support method that supports the task of calculating the costs of clients and servers that implement multiple tasks. In this method, requirements specification models capable of expressing various requirements specifications, and optimal configurations of client and server hardware and software for implementing the requirements specification models are prepared as system configuration models categorized into shared items and individual items.

Also, in this method, a requirements specification model is selected in accordance with a user's systematization task, and a system configuration model is selected for each of the selected requirements specification models. This method then integrates items that can be integrated in the selected system configuration model, integrates the unit costs of shared items and individual items per client and server in the system configuration model, and calculates the cost from the number of clients and servers.

In addition, the system configuration derivation device disclosed in Patent Document 4 generates system configuration information that indicates the configuration of a system that is free of undetermined parts, by concretizing the undetermined parts of abstract configuration information that indicates the configuration of a system that includes undetermined parts, using concretization rules.

Furthermore, Non-Patent Document 1 discloses implementation of refining the concretization target system configuration based on constraint conditions that must be satisfied by quantitative evaluation indexes, such as the performance required for the configuration components of the system. Specifically, in the system design method disclosed in Non-Patent Document 2, if multiple constraint conditions indicated in one system configuration cannot be all satisfied, the system configuration is excluded from being concretized.

### PRIOR ART DOCUMENTS

### Patent Documents

Patent Document 1: Japanese Unexamined Patent Application, First Publication No. 2021-135625
Patent Document 2: PCT International Publication No. WO 2019/244446
Patent Document 3: Japanese Unexamined Patent Application, First Publication No. H07-152809
Patent Document 4: PCT International Publication No. WO 2019/216082

### Non Patent Document

Takuya KUWAHARA, Takayuki KURODA, Takao OSAKI, Kozo SATODA, “An Intent-Based System Configuration Design for IT/NW Services with Functional and Quantitative Constraints”, IEICE Transactions on Communications Vol.E104-B, No.7, pp. 791-804, 2021.

### SUMMARY OF THE INVENTION

### Problems to be Solved by the Invention

In system design performed through repetitive application of concretization rules to system configurations, if it is possible to determine with greater accuracy whether or not a system configuration that is a system design candidate can satisfy constraint conditions, system configurations that cannot satisfy the constraint conditions can be excluded from the candidates, and in this respect, system design can be carried out efficiently.

In particular, it is preferable to be able to determine whether or not a plurality of configuration components of a system configuration can satisfy constraint conditions, not just two configuration components whose relationships are directly indicated.

An example object of the present invention is to provide a system design device, a system design method, and a recording medium capable of solving the problems mentioned above.

### Means for Solving the Problem

According to a first example aspect of the present invention, a system design device includes: a constraint condition generation means that selects one or more of configuration components of a target system configuration based on a configuration component selection method indicated in constraint condition generation information that is associated with system configuration information, wherein the system configuration information indicates a target system configuration, the target system configuration is one of target candidates for system design in which repetitive application of a concretization rule to a system configuration including an abstract configuration component is performed, the constraint condition generation information indicates a method of generating a constraint condition for the target system configuration, the constraint condition generation means generating a constraint condition for the target system configuration based on information set for the selected configuration component and the method of generating the constraint condition indicated in the concretization rule or the constraint condition generation information; a constraint validation means that determines whether or not the target system configuration can satisfy the constraint condition; a candidate refinement means that excludes the target system configuration from the target candidates for system design if the constraint validation means determines that the target system configuration cannot satisfy the constraint condition; and a concretization means that advances the system design by applying the concretization rule to the target candidates for the system design.

According to a second example aspect of the present invention, a system design device includes: a constraint condition generation information registration means that receives an input of constraint condition generation information indicating a method of generating a constraint condition that must be satisfied by a system configuration that is a candidate for system design in which repetitive application of a concretization rule to a system configuration including an abstract configuration component; a constraint condition generation means that generates a constraint condition that must be satisfied by a target system configuration, based on system configuration information that indicates the target system configuration that is one of the target candidates for system design and the constraint condition generation information; a constraint validation means that determines whether or not the target system configuration can satisfy the constraint condition; a candidate refinement means that excludes the target system configuration from the target candidates for the system design if the constraint validation means determines that the target system configuration cannot satisfy the constraint condition; and a concretization means that advances the system design by applying the concretization rule to the target candidates for the system design.

According to a third example aspect of the present invention, a system design method includes: selecting one or more of configuration components of a target system configuration based on a configuration component selection method indicated in constraint condition generation information that is associated with system configuration information, wherein the system configuration information indicates a target system configuration, the target system configuration is one of target candidates for system design in which repetitive application of a concretization rule to a system configuration including an abstract configuration component is performed, the constraint condition generation information indicates a method of generating a constraint condition for the target system configuration, generating a constraint condition for the target system configuration based on information set for the selected configuration component and the method of generating the constraint condition indicated in the concretization rule or the constraint condition generation information; determining whether or not the target system configuration can satisfy the constraint condition; excluding the target system configuration from the target candidates for system design if it is determined that the target system configuration cannot satisfy the constraint condition; and advancing the system design by applying the concretization rule to the target candidates for the system design.

According to a fourth example aspect of the present invention, a recording medium has stored therein a program causing a computer to execute: selecting one or more of configuration components of a target system configuration based on a configuration component selection method indicated in constraint condition generation information that is associated with system configuration information, wherein the system configuration information indicates a target system configuration, the target system configuration is one of target candidates for system design in which repetitive application of a concretization rule to a system configuration including an abstract configuration component is performed, the constraint condition generation information indicates a method of generating a constraint condition for the target system configuration, generating a constraint condition for the target system configuration based on information set for the selected configuration component and the method of generating the constraint condition indicated in the concretization rule or the constraint condition generation information; determining whether or not the target system configuration can satisfy the constraint condition; excluding the target system configuration from the target candidates for system design if it is determined that the target system configuration cannot satisfy the constraint condition; and advancing the system design by applying the concretization rule to the target candidates for the system design.

### Effect of Invention

According to the present invention, it is possible to determine whether or not multiple configuration components satisfy a constraint condition, even for configuration components other than those whose relationships are directly indicated among the configuration components of a system configuration.

### BRIEF DESCRIPTION OF THE DRAWINGS

FIG. 1 is a diagram showing a configuration example of a system design device according to a first example embodiment.

FIG. 2 is a diagram showing an example of an expression of a system configuration in the first example embodiment.

FIG. 3 is a diagram showing an example of a system configuration expressed in text in the first example embodiment.

FIG. 4 is a diagram showing an example of system requirements in the first example embodiment.

FIG. 5 is a diagram showing an example of definitions of configuration components in the first example embodiment.

FIG. 6 is a diagram showing an example of a definition of a relationship between configuration components in the first example embodiment.

FIG. 7 is a diagram showing an example of the definition of a concretization rule in the first example embodiment.

FIG. 8 is a diagram showing an example of concretization of a system configuration performed by the system design device according to the first example embodiment using system requirements, configuration components, and concretization rules.

FIG. 9 is a diagram showing a list of constraint conditions that must be satisfied by a system configuration obtained through the concretization of FIG. 8.

FIG. 10 is a diagram showing an example of a flow of processing performed by a constraint condition generation unit according to the first example embodiment by executing a configuration search means.

FIG. 11 is a flowchart showing an example of a procedure of processing performed by the system design device according to the first example embodiment.

FIG. 12 is a diagram showing an example of definitions of App_X2 representing a concrete application, Machine representing an abstract machine, and Machine_Z2 representing a concrete machine used in a second example embodiment.

FIG. 13 is a diagram showing an example of definitions of concretization rules used by the system design device in the second example embodiment.

FIG. 14 is a diagram showing an example of definitions of configuration components of a processing topology in the second example embodiment.

FIG. 15 is a diagram showing an example of the graphical representation of six types of relationships required to construct the processing topology in the second example embodiment.

FIG. 16 is a diagram showing an example of the textual representation of six types of relationships required to construct the processing topology in the second example embodiment.

FIG. 17 is a diagram showing a first example of the definition of a concretization rule of the processing topology in the second example embodiment.

FIG. 18 is a diagram showing a second example of the definition of a concretization rule of the processing topology in the second example embodiment.

FIG. 19 is a diagram showing a third example of the definition of a concretization rule of the processing topology in the second example embodiment.

FIG. 20 is a diagram showing a fourth example of the definition of a concretization rule of the processing topology in the second example embodiment.

FIG. 21 is a diagram showing a fifth example of the definition of a concretization rule of the processing topology in the second example embodiment.

FIG. 22 is a diagram showing an example of a definition of system requirements in the second example embodiment.

FIG. 23 is a diagram showing a first example of concretization of a system configuration in the second example embodiment.

FIG. 24 is a diagram showing a second example of concretization of a system configuration in the second example embodiment.

FIG. 25 is a diagram showing a third example of concretization of a system configuration in the second example embodiment.

FIG. 26 is a diagram showing a fourth example of concretization of a system configuration in the second example embodiment.

FIG. 27 is a diagram showing a fifth example of concretization of a system configuration in the second example embodiment.

FIG. 28 is a diagram showing a sixth example of concretization of a system configuration in the second example embodiment.

FIG. 29 is a flowchart showing an example of a processing procedure in which the constraint condition generation unit according to the second example embodiment generates constraint conditions.

FIG. 30 is a diagram showing an example of a constraint condition generated by the constraint condition generation unit according to the second example embodiment, based on a TATConstraintOf2 (1000, 20) function.

FIG. 31 is a diagram showing an example of a constraint condition generated by the constraint condition generation unit according to the second example embodiment based on a ResourceConstraintOf( ) function by using a constraint condition generation example 1.

FIG. 32 is a diagram showing an example of a constraint condition generated by the constraint condition generation unit according to the second example embodiment based on the ResourceConstraintOf( ) function by using a constraint condition generation example 2.

FIG. 33 is a diagram showing a configuration example of a system design device according to a third example embodiment.

FIG. 34 is a diagram showing a configuration example of a system design device according to a fourth example embodiment.

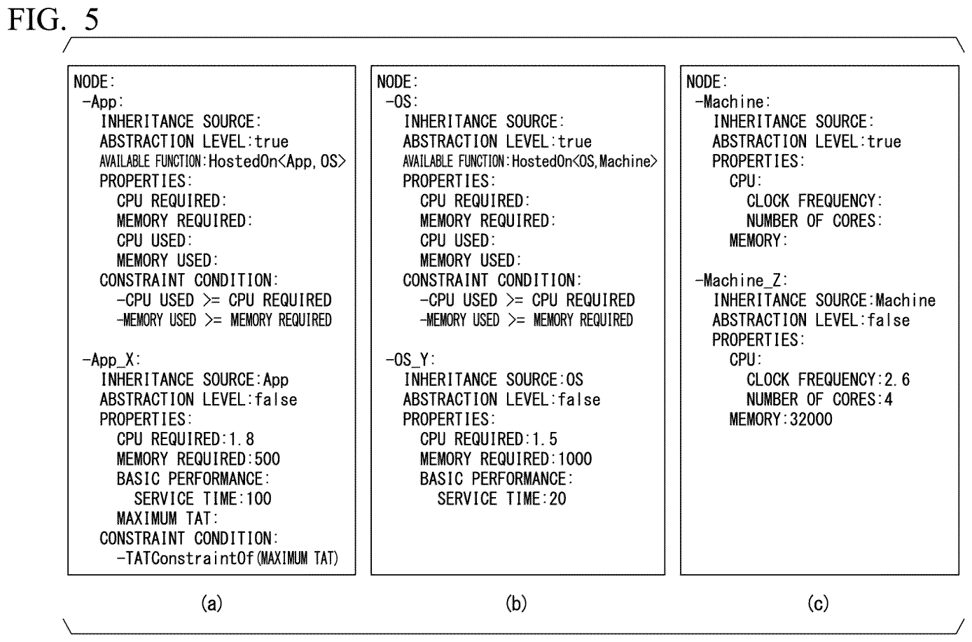

FIG. 5 is a diagram showing a configuration example of a system design device according to a fifth example embodiment.

FIG. 36 is a diagram showing an example of a processing procedure in a system design method according to a sixth example embodiment.

FIG. 37 is a schematic block diagram showing a configuration of a computer according to at least one example embodiment.

### EXAMPLE EMBODIMENTS

Hereinafter, example embodiments of the present invention will be described. However, the present invention within the scope of the claims is not limited by the following example embodiments. Furthermore, all the combinations of features described in the example embodiments may not be essential for the solving means of the invention.

### First Example Embodiment

### (Description of Configuration)

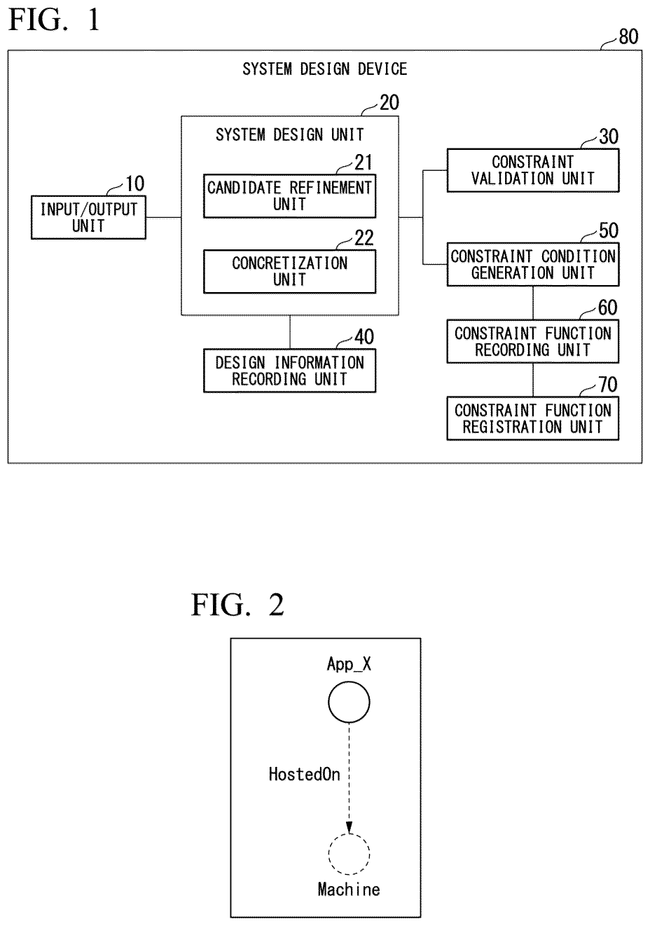

FIG. 1 is a block diagram showing a configuration example of a system design device according to a first example embodiment. In the configuration shown in FIG. 1, a system design device 80 includes an input/output unit 10, a system design unit 20, a constraint validation unit 30, a design information recording unit 40, a constraint condition generation unit 50, a constraint function recording unit 60, and a constraint function registration unit 70. The system design unit 20 includes a candidate refinement unit 21 and a concretization unit 22.

The system design device 80 performs system design by repetitively concertizing a system configuration indicated by input system requirements information, by applying concretization rules.

The system design device 80 may be configured, for example, with a computer such as a PC (personal computer) or a WS (workstation).

The system requirements information is information indicating requirements that a user of the system design device 80 expects from the design target system. The system requirements information includes information indicating a system configuration that the design target system must have. The system requirements information may further include information indicating functional requirements that the design target system must satisfy, and/or information indicating non-functional requirements that the design target system must satisfy.

The requirements indicated by the system requirements information are also referred to as system requirements. The user of the system design device 80 is also simply referred to as user.

System configuration information is information indicating a system configuration obtained during the system design performed by the system design device 80, or information indicating a concrete system configuration finally obtained through the system design performed by the system design device 80. The system configuration information includes information indicating a system configuration that is obtained as a result of repetitive concretization performed by applying concretization rules to a system configuration indicated by the system configuration information. The system configuration information is also simply referred to as configuration information.

The system configuration information may further include information indicating functional requirements included in the system requirements information as they are concretized according to the concretization of the system configuration, and/or information indicating non-functional requirements included in the system requirements information as they are concretized according to the concretization of the system configuration.

In the following description, an example will be described in which the system design device 80 performs automated system design. The automated design here means that the system design device 80 acquires the system design result after acquiring the system requirements information, without the need for user operation. The system design result here refers to information obtained as a result of system design performed by the system design device 80.

The system design device 80 acquires, as a system design result, information indicating a concrete system configuration that satisfies the system requirements, or information indicating a failure of system design. A failure in system design means the failure to obtain a concrete system configuration that satisfies the system requirements.

However, the system design device 80 may also be configured to receive instructions from the user in a case of designing a system. For example, in a case where the system design device 80 is selecting one of candidates for the concretization target system configuration, if the system design device 80 receives a user operation to designate one of the candidates, the designated candidate may be selected.

The input/output unit 10 inputs and outputs data to and from the outside of the system design device 80. The input/output unit 10 may include a display device such as a liquid crystal panel, and input devices such as a mouse and a keyboard, and function as a user interface. Furthermore, the input/output unit 10 may have a communication function and communicate with other devices.

The input/output unit 10 receives the input of system requirements and passes the input system requirements to the system design unit 20. Moreover, the input/output unit 10 receives configuration information of a concretized system configuration that satisfies the system requirements and is acquired as a result of the system design from the system design unit 20, and outputs the acquired configuration information. If the input/output unit 10 does not receive configuration information of a concretized system configuration that satisfies the system requirements from the system design unit 20, it may output an indication of a failure of system design.

The system design unit 20 acquires system requirements information from the input/output unit 10, and derives a system configuration that satisfies the system requirements. The concretization unit 22 of the system design unit 20 acquires concretization rules from the design information recording unit 40 according to the concretization target system configuration, and concretizes the system configuration in stages by applying the concretization rules to the concretization target system configuration.

The concretization unit 22 corresponds to an example of the concretization means.

Moreover, the candidate refinement unit 21 of the system design unit 20 passes system configuration information indicating the system configuration being designed to the constraint condition generation unit 50, and receives information indicating constraint conditions that the system configuration must satisfy. Furthermore, the candidate refinement unit 21 passes the constraint conditions included in the system configuration information and all the constraint conditions generated by the constraint condition generation unit 50 to the constraint validation unit 30. The candidate refinement unit 21 receives from the constraint validation unit 30 the verification result as to whether or not the system configuration being designed satisfies the constraint conditions. The candidate refinement unit 21 proceeds with concretizing the concretization target system configuration, limiting it to the system configuration that satisfies the constraint conditions.

Furthermore, the system design unit 20 returns to the input/output unit 10, the system configuration information or the information indicating a failure of system design obtained as a result of the system design.

The candidate refinement unit 21 corresponds to an example of the candidate refinement means.

The constraint validation unit 30 receives constraint conditions that the system configuration must satisfy from the system design unit 20, and validates whether or not the constraint conditions are conflicting. Then, the constraint validation unit 30 returns the verification result to the system design unit 20.

The constraint validation unit 30 corresponds to an example of the constraint validation means.

The design information recording unit 40 stores various information related to system configuration, such as definition information and concretization rules for system configuration components, and various information related to system configuration concretization. The design information recording unit 40 provides the above information in response to a request from the system design unit 20.

The constraint condition generation unit 50 receives the system configuration information of the system being designed from the system design unit 20. Furthermore, the constraint condition generation unit 50 receives from the constraint function recording unit 60 a constraint function in which a concrete means for outputting constraint conditions included in system configuration information is defined. The constraint condition generation unit 50 then generates constraint conditions based on the structure of the system configuration and the properties assigned to the system configuration, and returns the resulting constraint conditions to the system design unit 20.

The constraint condition generation unit 50 corresponds to an example of the constraint condition generation means.

The process in which the constraint condition generation unit 50 acquires system configuration information from the system design unit 20 and generates constraint conditions is performed not only for a system configuration that has already been concretized, but also for a system configuration that is still in the process of being designed. For example, each time the system design unit 20 applies one concretization rule to the system configuration being designed, the system design unit 20 may pass system configuration information to the constraint condition generation unit 50, which may then generate constraint conditions. However, the timing at which the constraint condition generation unit 50 generates constraint conditions is not limited to a particular timing.

The system configuration for which the constraint condition generation unit 50 generates constraint conditions is also referred to as a target system configuration. The target system configuration is a system configuration that is being determined as to whether or not to be excluded from system design, among the system configurations that are candidates for system design.

The constraint function recording unit 60 stores a constraint function, which is a function including a definition of a concrete means for outputting a constraint condition that must be satisfied by the system configuration, and returns the constraint function in response to a request from the constraint condition generation unit 50.

The constraint function recording unit 60 corresponds to an example of the constraint condition generation information storage means.

The constraint function is information including a definition of a concrete means for outputting a constraint condition that must be satisfied by the system configuration, and outputs the constraint condition. If the constraint function has arguments, it outputs a constraint condition according to the input argument values. The constraint function is referred to as a “function” because it outputs a constraint condition.

Specifically, the constraint condition generation unit 50 generates constraints by executing the means indicated by the constraint function.

The constraint function corresponds to an example of the constraint condition generation information, which is information indicating a constraint condition generation method.

However, the constraint condition generation information handled by the system design device 80 is not limited to being represented in the form of constraint functions. For example, the constraint condition generation information may be configured as a module (subroutine) without a return value, with the generated constraint conditions stored in a global variable.

Alternatively, the constraint condition generation information may be configured as simple information rather than a program, allowing the constraint condition generation unit 50 to reference this information while operating to generate the constraint conditions.

The constraint function registration unit 70 receives definition information of the constraint function as an input, and records the input definition information of the constraint function in the constraint function recording unit 60. The user can set a constraint function in the constraint function recording unit 60 via the constraint function registration unit 70.

The constraint function registration unit 70 corresponds to an example of the constraint condition generation information registration means.

The system requirements information and the system configuration information are further described below.

In both the system requirements information and the system configuration information, a system configuration is represented by nodes and edges. Nodes represent the components that make up the system, and edges represent the relationships between the components. The components and their relationships are collectively called configuration components. Any information that represents the characteristics of a configuration component can be set to the configuration component. Moreover, for a node or edge, a constraint condition can be set, which is a condition that the node or edge itself, or another node or edge, must satisfy.

FIG. 2 is a diagram showing an example of an expression of a system configuration.

In the example in FIG. 2, the circles represent nodes. The arrow connecting the circles indicate an edge. The name attached to the node indicates the type name of the configuration component. The name attached to the edge indicates the type name of the relationship. Dotted lines represent abstract configuration components and solid lines represent concrete configuration components.

FIG. 2 shows that the App_X node, representing a concrete application program, is operating on a machine of one sort or another. The system configuration shown in FIG. 2 uses nodes and an edge to express that “the App_X node is connected to the abstract Machine node through the HostedOn relationship”.

An application program is also referred to as an application.

The method of representing a system configuration is not limited to the graphical representation exemplified in FIG. 2. For example, a system configuration may be expressed in text. The method of representing a system configuration in text is not limited to a particular method. A variety of representations may be used that can uniquely transform a textual representation of a system configuration into a graphical representation of the system configuration.

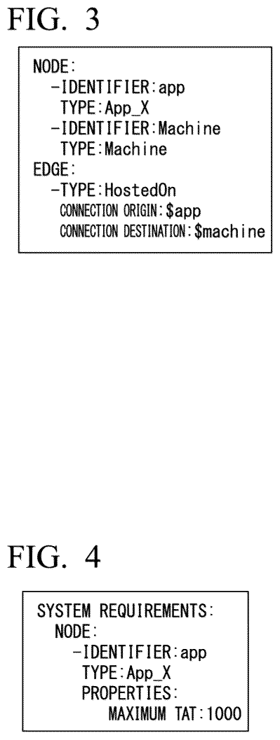

FIG. 3 is a diagram showing an example of the system configuration expressed in text.

A textually represented system configuration includes a list of nodes and a list of edges. Each node in the list of nodes is given an identifier that identifies the node and its node type. For each edge in the list of edges, the type of the edge, the identifier of the node from which the edge connects, and the identifier of the node to which the edge connects are indicated.

In FIG. 3, the symbol “$” indicates that the identifier for the variable name is referenced. For example, “$app” refers to the identifier named “app”.

FIG. 4 is a diagram showing an example of system requirements. System requirements are input by the user.

FIG. 4 shows a requirement to “construct an environment for the App_X node representing an application to operate”. Furthermore, in FIG. 4, as a performance requirement that the App_X node must satisfy, a maximum TAT value indicating a TAT (Turn Around Time) value that can be tolerated by the App_X node is set as a property. The example of FIG. 4 shows that the performance requirement for the operating environment of the App_X node is to build a system with a TAT of 1 second (=1000 milliseconds) or less.

In the following description using a specific example, it is assumed that a TAT requirement (requirement regarding a TAT value) is designated in the system requirements, and a specific example is used in which a system configuration that satisfies the TAT requirement is designed. However, the requirements handled by the system design device 80 are not limited to particular types of requirements.

Next, a method for defining configuration components and concretization rules will be described.

FIG. 5 is a diagram showing an example of definitions of configuration components.

As shown in FIG. 5, in the definition of a component, information on the inheritance source, abstraction level, available function, property, and constraint condition can be specified.

A configuration component is represented by a node, and therefore, the configuration component is also referred to as a node, and the definition of a configuration component is also referred to as the definition of a node. The node indicated in the definition is also referred to as a node type or configuration component type. In the example of FIG. 5, “App”, “App_X”, “OS”, “OS_Y”, “Machine”, and “Machine_Z” are referred to as node names and node type names.

The item “Inheritance source” indicates another configuration component (configuration component type) from which the configuration component to be defined inherits. No designation of the inheritance source means that nothing is inherited. By inheriting from another configuration component, it is possible to inherit the properties and constraint conditions of the configuration component of the inheritance source.

The item “Abstraction level” indicates whether the configuration component to be defined is an abstract component or a concrete component. The abstraction level is indicated by a flag value. If the abstraction level is true, it indicates that the configuration component is an abstract component. If the abstraction level is false, it indicates that the configuration component is a concretized component.

In system design, the system configuration is considered fully concretized in a case where the abstraction level of all configuration components included in the system configuration is false and all configuration components have relationships defined by available functions.

The item “Available function” indicates the relationship required by the configuration component being defined. In other words, the available function indicates that the configuration component to be defined must be connected to another configuration component in the relationship defined by the available function.

The item “Properties” is information that represents a characteristic or attribute of the configuration component to be defined. The user can freely designate a property according to the type of configuration component.

The item “Constraint condition” represents a condition that the configuration component to be defined must satisfy.

(a) in FIG. 5 shows the definition of a component called App (App node) that represents an abstract application, and the definition of a component called App_X (App_X node) that represents a concrete application. In the definition of the App node, the relationship HostedOn<App, OS> in the item “Available function” expresses that the application needs to be installed on an operating system (OS) of one sort or another in order to operate.

In general, for an application, the conditions required for the operation of the application (for example, minimum specifications (specifications, performance)) are designated. In order to incorporate such conditions into the system design, conditions can be set in the item “Properties”. In (a) of FIG. 5, properties of the required CPU and required memory are set for the App node, and properties representing the amount of CPU and memory resources available to the application in the system configuration being designed are set as CPU used and memory used.

Here, concrete values according to a concrete application are set for the required CPU and required memory. On the other hand, concrete values are not set in advance (before concretization of the system requirements is initiated) for the CPU used and memory used. The settings of the CPU used and memory used are used to determine whether or not there are concrete values that can satisfy the conditions designated as constraint conditions. In the App node of (a) of FIG. 5, the item “Constraint condition” indicates that the amount of CPU and memory resources available to the App node must be greater than or equal to the CPU required and the memory required.

The constraint condition designated for each configuration component affects the constraint conditions of other configuration components during the process of concretizing the system configuration. If the system design device 80 finally derives a system configuration that satisfies the constraint conditions set for all configuration components in the system configuration, the system design is completed.

For example, the constraint conditions that must be satisfied for a certain App node are that the CPU used is equal to or greater than the CPU required, and the memory used is equal to or greater than the memory required, as shown in the item “Constraint condition”. As mentioned above, the CPU used indicates a CPU that the App node can use. The memory used indicates the amount of memory available for the App node to use.

On the other hand, there is an upper limit on the CPU and memory that can be installed on the Machine node that hosts this App node. The CPU and memory available for the App node to use must be set to be at least equal to or less than the CPU and memory installed in the Machine node.

Thus, in the item “Constraint”, constraint conditions that must be satisfied by each configuration component or the entire system configuration are set.

In the definition of the App_X node in (a) of FIG. 5, the item “Inheritance source” indicates that the App_X node inherits from the App node. Moreover, a concrete value is set in the item “Properties”. The item “Properties” shows that the minimum specifications for running this application are a CPU of 1.8 GHz (gigahertz) or higher and a memory of 500 MB (megabytes) or more. Also, in the item “Properties”, 100 ms (milliseconds) is set as the service time of the App_X node as a method of expressing the basic performance of this App_X node.

Furthermore, in the item “Properties”, a maximum TAT property is set that designates the maximum allowable TAT as a performance requirement expected from this application. The concrete value of the maximum TAT is designated by the user in the system requirements as shown in the example of FIG. 4, for example.

As a method of expressing a constraint condition in the item “Constraint condition”, a concrete conditional expression may be directly set. Alternatively, as in the example of FIG. 5, a function for outputting a constraint condition may be indicated. As mentioned above, the function for outputting a constraint condition is referred to as a constraint function.

In the example of (a) of FIG. 5, “TATConstraintOf(maximum TAT)” represents a constraint function that outputs a concrete constraint condition related to the response time to satisfy a TAT value (maximum TAT) given as an input.

The definition of a configuration component related to an operating system shows items similar to those in the case of the definition of a configuration component related to an application. (b) of FIG. 5 shows the definition of an OS node representing an abstract operating system and the definition of an OS_Y node representing a concrete operating system.

The item “Properties” in the definition of OS_Y indicates the required resource value, the used resource value, and the basic performance value.

Also, (c) of FIG. 5 shows the definition of a Machine node representing an abstract machine and the definition of a Machine_Z node representing a concrete machine.

The item “Properties” in the definition of the Machine_Z node indicates the clock frequency and number of cores of the CPU of the machine represented by the Machine_Z node, as well as the concrete value of the memory.

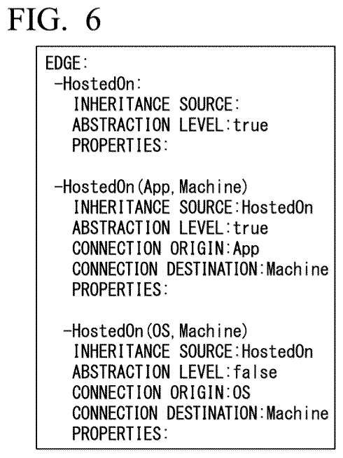

FIG. 6 is a diagram showing an example of a definition of the relationship between configuration components. In the definition of the relationship shown in FIG. 6, each item of the inheritance source, the abstraction level, the connection origin and connection destination, and the properties or some of these items are shown.

The inheritance source, abstraction level, and properties are the same as those in the case of configuration components.

The connection origin and connection destination indicate the type of the configuration component at the connection origin of the edge and the type of the configuration component at the connection destination of the edge. The type name being “*” means that no type is designated.

In FIG. 6, the relationship “HostedOn,” which indicates that one node is hosted on another node, is defined. Moreover, in FIG. 6, a relationship HostedOn (App, Machine) is defined which inherits the relationship of HostedOn and indicates that the connection origin and connection destination are an App node and a Machine node, respectively. Furthermore, in FIG. 6, a relationship HostedOn (OS, Machine) is defined which inherits the relationship of HostedOn and indicates that the connection origin and connection destination are an OS node and a Machine node, respectively.

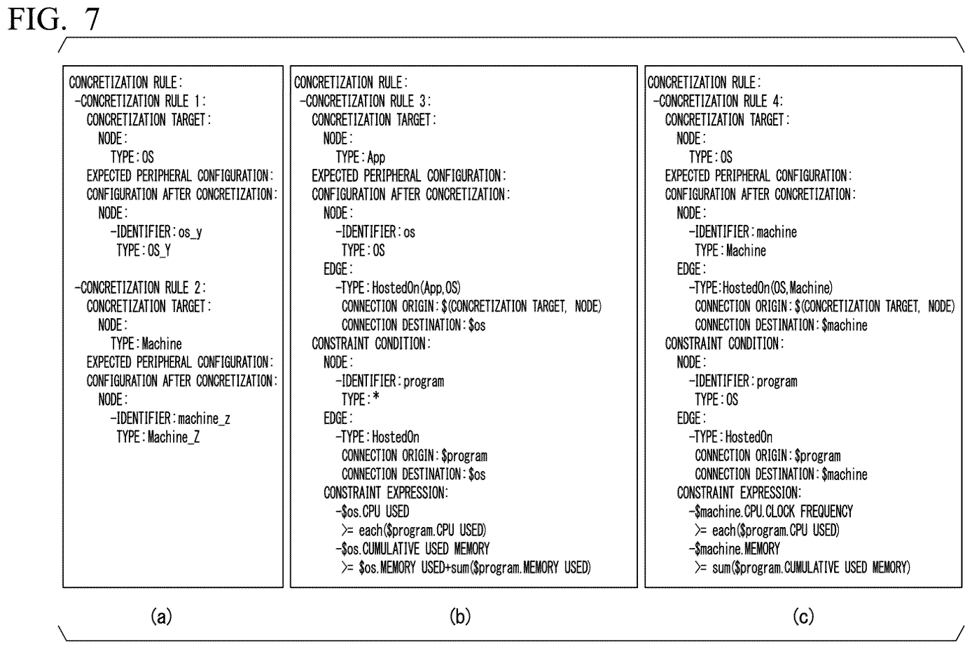

FIG. 7 is a diagram showing an example of the definition of a concretization rule. The definitions of concretization rules includes items such as concretization target, expected peripheral configuration, post-concretization configuration, and constraint conditions, or some of these.

The item “Concretization target” indicates a target of concretization (concretization target). A node or an edge is designated as the concretization target.

The item “Expected peripheral configuration” indicates a configuration that must be satisfied in the periphery of the concretization target as a prerequisite for concretizing the concretization target. For example, in a case of defining a concretization rule that applies only to an “OS node with an application of one sort or another running thereon” rather than to any OS node, configuration information “an App node is connected to an OS node by an edge called HostedOn (App, OS)” can be written in the item “Expected peripheral configuration” as an expected peripheral configuration.

The item “post-concretization configuration” indicates how the configuration of the concretization target node or edge is changed after concretization.

The item “Constraint condition” represents a constraint condition that a configuration component must satisfy in a case of applying the concretization rule.

The concretization rule 1 defined in the example of FIG. 7 is a concretization rule whereby an abstract OS node is concretized into a concrete ode, OS_Y. The concretization rule 2 is a concretization rule whereby an abstract Machine node is concretized into a concrete node, Machine_Z.

The concretization rule 3 is a concretization rule that targets an App node and concretizes the relationship in which in order for an application to operate, an OS node hosting the application is required. The concretization rule 3 indicates that a new OS node is generated and the App node and the OS node are connected with an edge called HostedOn (App, OS).

Furthermore, the item “Concretization rule” in the concretization rule 3 indicates the constraint condition that each configuration component must satisfy in a case where the concretization rule 3 is applied to a system configuration. Specifically, the item “Constraint Condition” indicates a constraint condition such that the CPU specifications available to the operating system are greater than or equal to the CPU specifications available to the programs connected through the relationship between the OS node and HostedOn, and that the sum of the amount of memory available to these programs and the amount of memory available to the operating system itself is less than or equal to the value of the cumulative memory usage, which is a variable held by the OS node.

The programs connected through the relationship between the OS node and HostedOn is represented by an identifier “program” in the concretization rule 3 of FIG. 7.

This constraint condition also assumes that multiple applications are installed on an operating system. This constraint condition indicates that the CPU specifications available to the operating system must be greater than or equal to the CPU specifications required by each of one or more applications installed on the operating system, and that the cumulative memory usage (the amount of available memory) recognized by the operating system must be greater than or equal to the sum of the memory usage amount of each application installed on the operating system and the memory usage amount of the operating system itself.

The constraint expressions indicated by constraint conditions of the concretization rules correspond to examples showing a constraint condition generation method indicated in the concretization rules. The concretization unit 22 concretizes a system configuration through the concretization rule application, whereby the constraint expressions are also concretized.

The constraint condition generation unit 50 generates constraint conditions by inputting values into constraint expressions. The constraint condition generation unit 50 extracts values indicated in the properties of the configuration components of the system configuration, based on the constraint functions, and inputs the extracted values into the constraint expressions. Alternatively, the constraint validation unit 30 may input values to the constraint expressions in a case of determining whether or not the system configuration satisfies the constraint conditions.

In the example of FIG. 7, both the constraint expression “$os.CPU used>=each ($program.CPU used)” and the constraint expression “$os.Cumulative memory usage>=$os.Memory used+sum ($program.Memory used)” correspond to examples of the constraint condition generation method indicated in the concretization rules.

A character string beginning with “$” indicates a portion that will be concretized through concretization of the system configuration performed by the concretization unit 22. For example, in “$program.CPU Used”, “$program” is replaced with the program node type, such as operating system or application. For example, if “$program.CPU used” is replaced with “App_X.CPU used”, the constraint condition generation unit 50 replaces this portion with the value indicated in the property, “CPU used” of the App_X node.

Both “each” and “sum” in the constraint expression can be expanded into multiple nodes that the constraint condition generation unit 50 extracts by executing a constraint function configuration search means, which will be described later. For “each”, the constraint condition generation unit 50 generates a constraint expression for each extracted node. For “sum”, the constraint condition generation unit 50 expands the term “sum” into the sum of the values indicated in the property of each extracted node.

The concretization rule 4 is a concretization rule that concretizes the relationship in which in order for an operating system indicated by an OS node to operate, a machine on which the operating system is installed is required. The concretization rule 4 indicates that an OS node is to be concretized, a new Machine node is to be generated, and the OS node and the Machine node are to be connected with an edge called HostedOn (OS, Machine).

The item “Constraint condition” in the concretization rule 4 indicates constraint conditions that also take into account the case where multiple operating systems are installed on one machine. The constraint conditions indicate that the CPU specifications of the machine are higher or equal to the CPU specifications required by each of one or more of the operating systems, and the amount of memory installed in the machine is higher or equal to the total memory usage recognized by each OS node hosted by the Machine node, that is, the sum of memory usage amount including memory usage amount used by applications installed on each operating system.

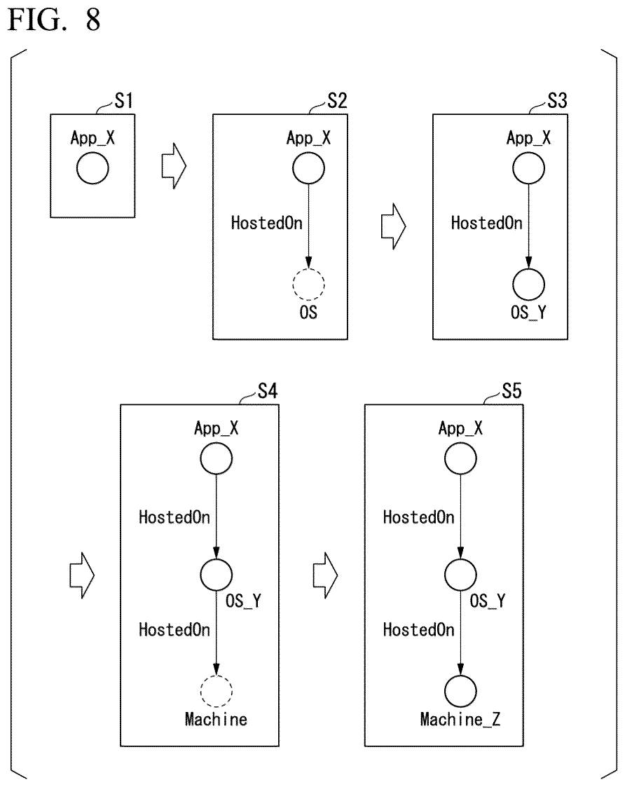

FIG. 8 is a diagram showing an example of concretization of a system configuration performed by the system design device 80, using system requirements, configuration components, and concretization rules defined in FIG. 4 to FIG. 7.

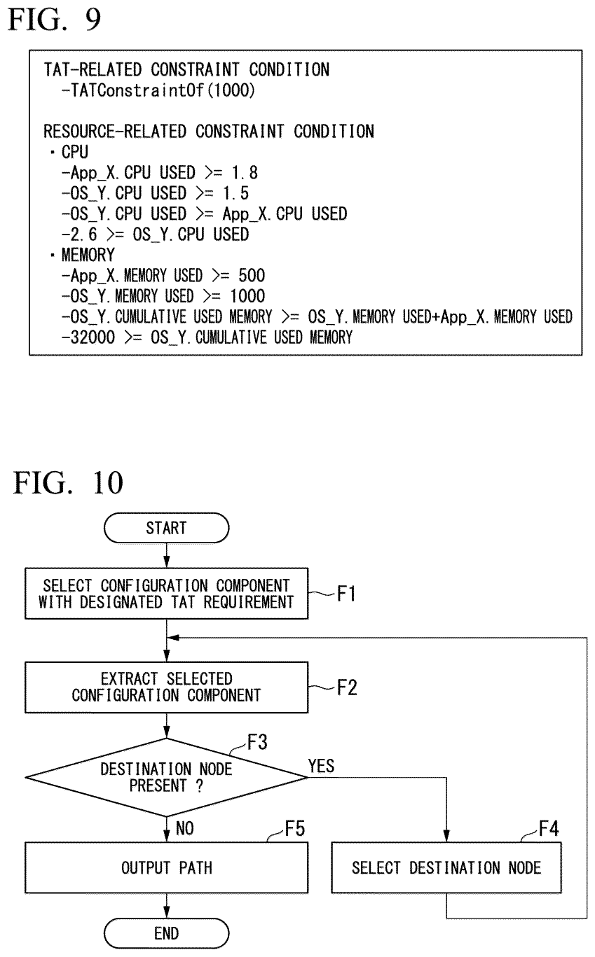

FIG. 9 is a diagram showing a list of constraint conditions that must be satisfied by the system configuration obtained through the concretization of FIG. 8.

A system requirement S1 of FIG. 8 shows the system requirement of FIG. 4.

In the example of FIG. 8, the system design device 80 starts system design with the system requirement S1 serving as the concretization target. Then, the system design device 80 acquires a system configuration S2 in which an OS node required for the App_X node to operate is provided by applying the concretization rule 3 of FIG. 7 to the system requirement S1.

Next, the system design device 80 acquires a system configuration S3 in which the OS node is concretized into an OS_Y node by concretizing the system configuration S2 by applying the concretization rule 1. Thereafter, the system design device 80 acquires a system configuration S4 in which a machine node necessary for the OS to operate is provided, by concretization through application of the concretization rule 4 to the system configuration S3.

Then, the system design device 80 acquires a system configuration S5 in which the Machine node is concretized into a Machine_Z node by concretization through application of the concretization rule 2 to the system configuration S4.

Moreover, the system design device 80 acquires a list of constraint conditions shown in FIG. 9 based on the constraint conditions designated by the types of configuration components and the constraint conditions designated by the concretization rules in the system design shown in FIG. 8.

Specifically, in a case of applying the concretization rule 3 to the system requirement S1, the system design device 80 substitutes the property “Maximum TAT: 1000” indicated in the system requirement of FIG. 4 into the constraint condition “TATConstraintOf (Maximum TAT)” indicated in the definition of the App_X node in (a) of FIG. 5, thereby acquiring the constraint condition “TATConstraintOf(1000)” shown in FIG. 9.

Moreover, in a case of applying the concretization rule 3 to the system requirement S1, the system design device 80 substitutes the property “CPU required: 1.8” indicated in the definition of the App_X node into the constraint condition “CPU used>=CPU required” indicated in the definition of the App node in FIG. 5(a), thereby acquiring the constraint condition “CPU used>=1.8” shown in FIG. 9.

Furthermore, in a case of applying the concretization rule 3 to the system requirement S1, the system design device 80 substitutes the property “Memory required: 500” indicated in the definition of the App_X node into the constraint condition “Memory used>=Memory required” indicated in the definition of the App node in (a) of FIG. 5, thereby acquiring the constraint condition “Memory used>=500” shown in FIG. 9.

Also, in a case of applying the concretization rule 1 to the system configuration S2, the system design device 80 substitutes the property “CPU required: 1.5” indicated in the definition of the OS_Y node into the constraint condition “CPU used>=CPU required” indicated in the definition of the OS node in (b) of FIG. 5, thereby acquiring the constraint condition “CPU used>=1.5” shown in FIG. 9.

Moreover, in a case of applying the concretization rule 1 to the system requirement S2, the system design device 80 substitutes the property “Memory required: 1000” indicated in the definition of the OS_Y node into the constraint condition “Memory used>=Memory required” indicated in the definition of the OS node in (b) of FIG. 5, thereby acquiring the constraint condition “Memory used>=1000” shown in FIG. 9.

Also, in a case of applying the concretization rule 3 to the system requirement S1, the system design device 80 substitutes “type: APP_X” indicated in the system requirement of FIG. 4 into the constraint expression “$os.CPU used>=each($program.CPU used)” indicated in the definition of the concretization rule 3 of FIG. 7, thereby acquiring the constraint expression “$os.CPU used>=App_X.CPU used”.

Furthermore, in a case of applying the concretization rule 1 to the system configuration S2, the system design device 80 substitutes the type “OS_Y” indicated in the definition of OS_Y of FIG. 5 into the constraint expression “$os.CPU used>=App_X.CPU used”, thereby acquiring the constraint condition “OS_Y.CPU used>=App_X.CPU used” shown in FIG. 9.

Also, in a case of applying the concretization rule 3 to the system requirement S1, the system design device 80 substitutes “Type: APP_X” indicated in the system requirement of FIG. 4 into the constraint expression “$os.Cumulative memory usage>=$os.Memory used+sum ($program.Memory used)” indicated in the definition of the concretization rule 3 of FIG. 7, thereby acquiring the constraint expression

$$“ \$ os . Cumulative memory usage >= \$ os . Memory used + App\_X . Memory used ” .$$

Furthermore, in a case of applying the concretization rule 1 to the system configuration S2, the system design device 80 substitutes the type “OS_Y” indicated in the definition of the OS_Y node of FIG. 5 into the constraint expression “$os.Cumulative memory usage>=$os.Memory used+App_X.Memory used”, thereby acquiring the constraint condition “OS_Y.Cumulative memory usage>=OS_Y.Memory used+App_X.Memory used” shown in FIG. 9.

Moreover, in a case of applying the concretization rule 4 to the system configuration S3, the system design device 80 substitutes the type “OS_Y” indicated in the system configuration S4 into the constraint expression “$machine.CPU.clock frequency>=each ($program.CPU used)” indicated in the concretization rule 4, thereby acquiring the constraint expression “$machine.CPU.clock frequency>=OS_Y.CPU used”. Then, in a case of applying the concretization rule 2 to the system configuration S4, the system design device 80 substitutes the property “CPU: Clock frequency: 2.6” indicated in the definition of Machine_Z in (c) of FIG. 5 into the constraint expression “$machine.CPU.Clock frequency>=OS_Y.CPU used”, thereby acquiring the constraint condition “2.6>=OS_Y.CPU used” shown in FIG. 9.

Also, in a case of applying the concretization rule 4 to the system configuration S3, the system design device 80 substitutes the type “OS_Y” indicated in the system configuration S4 into the constraint expression “$machine. Memory>=sum ($program. Cumulative memory usage)” indicated in concretization rule 4, thereby acquiring the constraint expression “$machine. Memory>=OS_Y.Cumulative memory usage”. Then, in a case of applying the concretization rule 2 to the system configuration S4, the system design device 80 substitutes the property “Memory: 32000” indicated in the definition of Machine_Z in (c) of FIG. 5 into the constraint expression “$machine.Memory>=OS_Y.Cumulative memory usage”, thereby acquiring the constraint condition “32000>=OS_Y.Cumulative memory usage” shown in FIG. 9.

In the system configuration S5, there are no abstract configuration components in the system configuration, and the relationships required for the available functions of respective configuration components are also satisfied. Therefore, the system design device 80 acquires the concrete system configuration S5.

On the other hand, for the system design to be successfully completed, all constraint conditions indicated in the configuration components of the system configuration and all constraint conditions indicated in the applied concretization rules must be satisfied. If the constraint conditions that must be satisfied by the system configuration S5 shown in FIG. 9 are not conflicting, that is to say, if there are values that satisfy all of these constraint conditions, it can be said that the constraint conditions of the system configuration are satisfied. Here, for a constraint condition regarding response time, a constraint function is designated instead of a concrete conditional expression, and thus, the constraint condition generation unit 50 generates a concrete constraint condition.

In the following, the constraint function handled by the system design device 80 will be described, and then the flow of processing in which the constraint condition generation unit 50 generates a constraint condition based on the constraint function will be described.

The constraint function is a function that outputs a constraint condition that a system configuration must satisfy, and a configuration search means and a constraint generation means are defined. These definitions may be implemented in any manner that describes data processing, and may for example be written in a common programming language such as Python.

For example, the constraint function may be configured as a function in a program, and the configuration search means and the constraint generation means may each be configured as a module (subroutine) executed within the function. However, as described above, the constraint condition generation information handled by the system design device 80 is not limited to information expressed in the form of a constraint function.

The configuration search means is a means for extracting a specific configuration component from the system configuration. The constraint generation means is a means for generating a constraint condition based on information on the configuration component extracted by the configuration search means. An example of the configuration search means is a method of extracting a series of configuration components that are linked in a chain of relationships, such as a configuration component that hosts a designated application and a configuration component that further hosts that configuration component, as configuration components that affect the performance of an application for which a TAT requirement is designated.

FIG. 10 is a diagram showing an example of a flow of processing performed by the constraint condition generation unit 50 by executing the configuration search means. In the processing shown in FIG. 10, the constraint condition generation unit 50 receives as input a system configuration in which a TAT requirement is designated among the configuration components of the system (Step F1), and extracts the configuration components thereof (Step F2).

Thereafter, the constraint condition generation unit 50 searches the system configuration and determines whether or not there is a HostedOn edge whose connection origin is the configuration component extracted in Step F2 (Step F3). If a corresponding HostedOn edge is determined as being present (Step F3: YES), the constraint condition generation unit 50 selects a destination node of the HostedOn edge (Step F4).

After Step F4, the processing returns to Step F2.

On the other hand, if it is determined in Step F3 that there is no corresponding HostedOn edge (Step F3: NO), the constraint condition generation unit 50 outputs all the configuration components extracted up to that point (Step F5).

After Step S5, the constraint condition generation unit 50 ends the processing of FIG. 10.

As a specific example of the processing performed by the constraint condition generation unit 50 executing the constraint generation means, it is conceivable to generate a constraint condition such that the total service time set for the configuration components extracted by the configuration search means should be less than or equal to the maximum TAT value designated by the argument of the constraint function.

The flow of the processing for generating concrete constraint conditions in a case where the constraint condition generation unit 50 receives the system configuration shown in S5 of FIG. 8, which includes the constraint function TATConstraintOf( ) having the configuration search means and constraint generation means exemplified above, will be described below. A constraint function name such as “TATConstraintOf” corresponds to an example of constraint function identification information for identifying a constraint function. The constraint function identification information corresponds to an example of constraint condition generation information identification information for identifying constraint condition generation information.

The constraint condition generation unit 50 receives the constraint function TATConstraintOf(1000) in which a maximum TAT value of 1 second is set for App_X, and starts the processing of FIG. 10.

In Step F1 of FIG. 10, the constraint condition generation unit 50 selects App_X for which a TAT requirement is designated.

Next, in the loop of Step F2 to Step F4, the constraint condition generation unit 50 selects configuration components of the OS_Y node that are connected to the App_X node by the edge of HostedOn, and extracts the OS_Y node. Similarly, the constraint condition generation unit 50 selects the configuration components of the Machine_Z node that are connected to the OS_Y node by the edge of HostedOn, and extracts the Machine_Z node.

Since the Machine_Z node does not have a HostedOn edge from which it is the connection origin, the processing transitions to Step F5, and the constraint condition generation unit 50 outputs the extracted App_X node, OS_Y node, and Machine_Z node. Then, the constraint condition generation unit 50 ends the processing of FIG. 10.

After the processing of FIG. 10, the constraint condition generation unit 50 executes the constraint generation means and generates a constraint condition such that the sum of the service times of the three extracted configuration components is less than or equal to the maximum TAT value, based on the maximum TAT value designated in the system requirements and the three extracted configuration components. Specifically, the constraint condition generation unit 50 generates a constraint condition “maximum TAT value>=App_X. Service time+OS_Y.Service time+Machine_Z. Service time”. The constraint condition generation unit 50 returns the generated constraint condition to the system design unit 20.

The constraint generation means of the constraint function TATConstraintOf( ) in the first example embodiment can be said to indicate a constraint condition generation method such that the sum of the service times of the three extracted configuration components is less than or equal to the designated maximum TAT value. Thus, the constraint generation means corresponds to an example showing the constraint condition generation method shown in a constraint function.

The expression form of the constraint generation means is not limited to a particular form. For example, the constraint generation means may be configured as a program, such as a subroutine as mentioned above. Alternatively, the constraint generation means may be configured as information indicating an algorithm.

In the case where concrete values are set for the properties of each configuration component, the constraint validation unit 30 determines whether or not the constraint conditions are satisfied based on those values. For example, the constraint condition generation unit 50 may generate and output constraint conditions including the values of those properties.

In the example of FIG. 5, concrete values are set for App_X.Service time and OS_Y.Service time. The constraint validation unit 30 determines that the constraint conditions are satisfied, based on these concrete values.

It should be noted that no service time value is set for the Machine_Z node. Accordingly, the constraint validation unit 30 determines whether or not the constraint condition is satisfied where the service time of the Machine_Z node is treated as 0.

As described above, the processing of constraint condition generation in the constraint condition generation unit 50 is performed not only for a concretized system configuration in which no abstract configuration components are present, such as S5 in FIG. 8, but also for system configurations in the process of being concretized, as shown in S2 to S4 in FIG. 8. This is to exclude system configurations that cannot satisfy constraint conditions at an intermediate design stage from the list of design candidates as early as possible, thereby enabling system design to be completed in a shorter period of time.

In a case of generating constraint conditions for a system configuration that is in the process of concretization, the constraint condition generation unit 50 generates the constraint conditions within the range of information included in the system configuration information. For example, in a case of the constraint condition generation unit 50 generates constraint conditions for the system configuration indicated with S2 of FIG. 8, neither an OS_Y node indicating concrete performance values nor a Machine_Z node indicating concrete performance values is present within the system configuration. Therefore, the constraint condition generation unit 50 generates the constraint conditions by taking into account only the configuration components of the App_X node.

As mentioned above, the constraint validation unit 30 determines whether or not the system configuration satisfies the constraint conditions.

For example, the system design unit 20 passes the system configuration information, which is subject to constraint conditions as shown in FIG. 9, to the constraint validation unit 30. For the constraint condition related to response time, the system design unit 20 replaces the constraint function with the concrete constraint condition “Maximum TAT value>=App_X.Service time+OS_Y.Service time+Machine_Z.Service time” received from the constraint condition generation unit 50, and passes it to the constraint validation unit 30 together with the concrete values set in the properties of the configuration components.

In the example of FIG. 9, where the values App_X.Available CPU=2.0, App_X.Available memory=2000, OS_Y.Available CPU=2.0, and OS_Y.Available memory=2000, are presented, it can be determined that all of these constraint conditions can be satisfied without a conflict. Accordingly, the constraint validation unit 30 returns to the system design unit 20 information indicating that the constraint conditions are satisfied.

Thus, if the CPU specification available to the App_X node is 2.0 GHz and the memory size is 2 GB, this satisfies the amount of resources required for the App_X node to operate. Similarly, if the CPU specification available to the OS_Y node is 2.0 GHz and the memory size is 2 GB, this satisfies the amount of resources required for the OS_Y node to operate.

Here, the Machine_Z node is equipped with a 2.6 GHz CPU and a 32 GB memory size, and it can be determined that there will be no issues if the App_X node and OS_Y node use the above required resources. Therefore, the constraint validation unit 30 can determine that it is possible to build a system configuration that satisfies all of the designated constraint conditions.

### (Description of Operation)

Next, the operation of the system design device 80 according to the first example embodiment will be described.

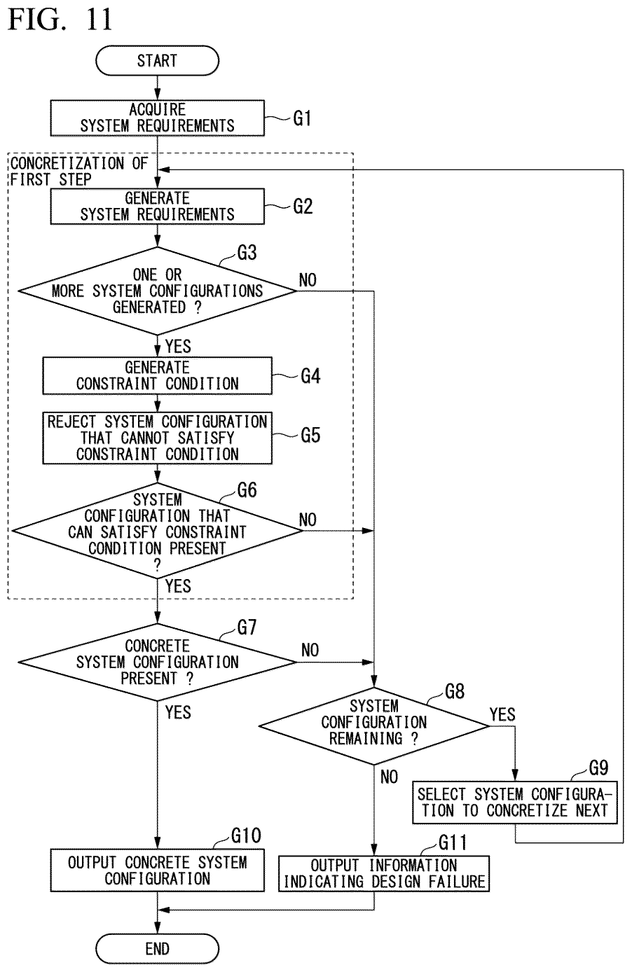

FIG. 11 is a flowchart showing an example of a procedure of processing performed by the system design device 80 according to the first example embodiment. In the processing of FIG. 11, the input/output unit 10 acquires system requirements input by the user (Step G1).

Next, the system design unit 20 concretizes in a stepwise manner the system requirements obtained in Step G1 (Step G2 to Step G9), and outputs either a completely concretized system configuration or a failure of system design (Step G10, Step G11).

As a stepwise concretization, the system design unit 20 first performs one step of concretization (Step G2 to Step G6) and determines whether the resulting system configuration in progress of being designed includes a concrete system configuration (Step G7). A concrete system configuration is a system configuration in which there are no abstract configuration components and in which the relationships required by the configuration component as available functions are satisfied.

If it is determined that a concrete system configuration is included (Step G7: YES), the system design unit 20 outputs the obtained concrete system configuration via the input/output unit 10 (Step G10).

After Step G10, the system design device 80 ends the processing of FIG. 11.

On the other hand, if it is determined in Step G7 that a concrete system configuration is not included (Step G7: NO), the system design unit 20 determines whether any abstract system configurations in the process of being designed remain (Step G8).

If it is determined that any abstract system configuration in the process of being designed remains (Step G8: YES), the system design unit 20 selects the system configuration in the process of being designed to be concretized next (Step G9). The method for the system design unit 20 to select the system configuration in the process of being designed to be concretized next is not limited to a particular method.

After Step G9, the processing returns to Step G2.

On the other hand, if it is determined in Step G8 that there is no abstract system configurations remaining in the designing process (Step G8: NO), the system design unit 20 outputs information indicating a failure of the designing via the input/output unit 10 (Step G11). This is because there are no system configurations remaining to concretize, and no further concretization can be performed.

After Step G11, the system design device 80 ends the processing of FIG. 11.

In the one step of concretization, the system design unit 20 generates a system configuration by applying applicable concretization rules to the system requirements input in Step G1 or the system configuration selected in Step G9 (Step G2).

Then, the system design unit 20 determines whether or not one or more system configurations have actually been generated in Step G2 (Step G3).

If the system design unit 20 determines that system configurations have not been generated (Step G3: NO), the processing proceeds to Step G8. In such a case, the concretization of one step has failed. Thus, the system design device 80 proceeds to concretization of another system configuration that is in the process of being designed.

On the other hand, if the system design unit 20 determines in Step G3 that one or more system configurations have been generated (Step G3: YES), the constraint condition generation unit 50 generates constraint conditions for each generated system configuration, based on the constraint functions included in the system configuration (Step G4).

Thereafter, the constraint validation unit 30 determines, for each system configuration generated in Step G2, whether or not all of the constraint conditions given to the system configuration can be satisfied, and discards any system configuration that cannot satisfy the constraint conditions (Step G5). Thus, by discarding system configurations in the process of being designed that leads to a system configuration that cannot satisfy the system requirements at an early step of concretizing the system configuration, the efficiency of system design can be improved.

Thereafter, the system design unit 20 determines whether or not one or more system configurations remain that can satisfy the constraint conditions (Step G6).

If the system design unit 20 determines that there remains a system configuration that can satisfy the constraint conditions (Step G6: YES), the processing proceeds to Step G7. In such a case, it can be said that the system design device 80 has succeeded in the concretization of the one step, and it is therefore determined whether or not the remaining system configurations are concrete.

On the other hand, if the system design unit 20 determines in Step G6 that there is no system configurations remaining that can satisfy the constraint conditions (Step G6: NO), the processing proceeds to Step G8. In such a case, it can be said that the concretization of the one step has failed, and therefore the system design device 80 proceeds to concretization of another system configuration that is in the process of being designed.

### (Description of Effect)

According to the first example embodiment, concrete constraint conditions that the designing target system must satisfy are generated based on the structure of the system configuration and the assigned properties, making it possible to design a high-quality system that more accurately satisfies requirements for the system.

As described above, the constraint condition generation unit 50 selects one or more of configuration components of a target system configuration based on a configuration component selection method indicated in constraint condition generation information that is associated with system configuration information, the system configuration information indicating a target system configuration, the target system configuration being one of target candidates for system design in which repetitive application of a concretization rule to a system configuration including an abstract configuration component is performed, the constraint condition generation information indicating a method of generating a constraint condition for the target system configuration, and generates a constraint condition for the target system configuration by applying the method of generating the constraint condition indicated in the system configuration information or the constraint condition generation information. The constraint validation unit 30 determines whether or not the target system configuration can satisfy the constraint conditions. The candidate refinement unit 21 excludes the target system configurations from the target candidates for system design if the constraint validation unit 30 determines that the target system configurations cannot satisfy the constraint conditions. The concretization unit 22 applies the concretization rules to the target candidates for system design to advance the system design.

According to the system design device 80, it is possible to determine whether or not multiple configuration components satisfy constraint conditions, even for configuration components other than those whose relationships are directly indicated among the configuration components of the system configuration. For example, according to the system design device 80, it is possible to generate constraint conditions for multiple nodes extracted based on the configuration search means, not limited to nodes directly connected by edges, and to determine whether or not the system configurations can satisfy the constraint conditions. According to the system design device 80, it is possible to exclude system configurations that cannot satisfy constraint conditions from candidates for system design, and in this respect, this enables efficient system design.

Moreover, the constraint function recording unit 60 stores constraint functions. The constraint function includes constraint function identification information for identifying the constraint function itself. The system configuration information with which the constraint function is associated includes constraint function identification information for identifying the associated constraint function.

According to the system design device 80, it is possible to acquire the constraint function through a relatively simple method in which the constraint function identification information is extracted by referring to the system configuration information, and the constraint function is acquired from the constraint function recording unit 60 based on the constraint function identification information.

Furthermore, the constraint function registration unit 70 receives input of a new constraint function, and stores the input constraint function in the constraint function recording unit 60.

According to the system design device 80, the user can register a desired constraint function. In this respect, according to the system design device 80, it is possible to design a system that satisfies the conditions desired by the user.

### Second Example Embodiment

### (Description of Configuration)

Next, a system design device according to a second example embodiment will be described.

The configuration of the system design device according to the second example embodiment is similar to that in the case of the first example embodiment. The second example embodiment will also be described using the configuration of the system design device 80 shown in FIG. 1.

In the second example embodiment, in a case of evaluating a system configuration, the system design device 80 generates constraint conditions related to processes executed in the system configuration, in addition to the constraint conditions generated in the first example embodiment. Thereby, the system design device 80 according to the second example embodiment evaluates the system configuration with higher accuracy than in the first example embodiment. In other respects, the second example embodiment is similar to the case of the first example embodiment.

In the second example embodiment, the system configuration further includes a processing topology that models the processing executed on the system. In this processing topology, it is possible to represent the flow of processing executed on the system, the types of resources used in each process, and the sharing status of resources by each process. In a case of generating constraint conditions that must be satisfied by the system, the constraint condition generation unit 50 generates the constraint conditions based on the flow of processing executed on the system, including this processing topology, and the resource usage status. This allows the constraint condition generation unit 50 to set the constraint conditions that must be satisfied by the system configuration in more detail.

What is referred to as a system configuration in the first example embodiment is referred to as a configuration topology in the second example embodiment. In the second example embodiment, a combination of a configuration topology and a processing topology is referred to as a system configuration.

The system configuration in the first example embodiment corresponds to an example of the system configuration in the second example embodiment in which illustration of the processing topology is omitted.

In the second example embodiment, the constraint condition generation unit 50 also generates constraint conditions on resource usage that each configuration component must satisfy, which is defined in the concretization rules in the first example embodiment. A design information recording unit 40 in the second example embodiment also stores, as system configuration information, information on the configuration components of the processing topology and information on the concretization rules of the processing topology. The concretization rules of a processing topology are the concretization rules for concretizing a processing topology. In response to a request from the system design unit 20, the design information recording unit 40 returns information on the configuration components of the processing topology as well as information on the concretization rules of the processing topology.

The system design unit 20 in the second example embodiment also concretizes a processing topology during system design. Specifically, in a case where the system design unit 20 selects one concretization rule to be applied to a system configuration in the process of being designed, the system design unit 20 selects either the concretization rule shown in the first example embodiment or the concretization rule of a processing topology. The method in which the system design unit 20 selects the concretization rule is not limited to a particular method. For example, the system design unit 20 may randomly select a concretization rule, or may preferentially select a concretization rule for a processing topology.

The constraint condition generation unit 50 in the second example embodiment generates a constraint condition on response time and a constraint condition on resource usage, based on the processing topology. Accordingly, in the second example embodiment, the definitions of the configuration components, the definitions of the concretization rules, and the definitions of the system requirements are also changed from those in the first example embodiment.

First, examples of definitions of system configuration components used in the second example embodiment and examples of definitions of concretization rules will be shown as additions to the first example embodiment, and then data related to the processing topology that is newly handled in the second example embodiment will be described.

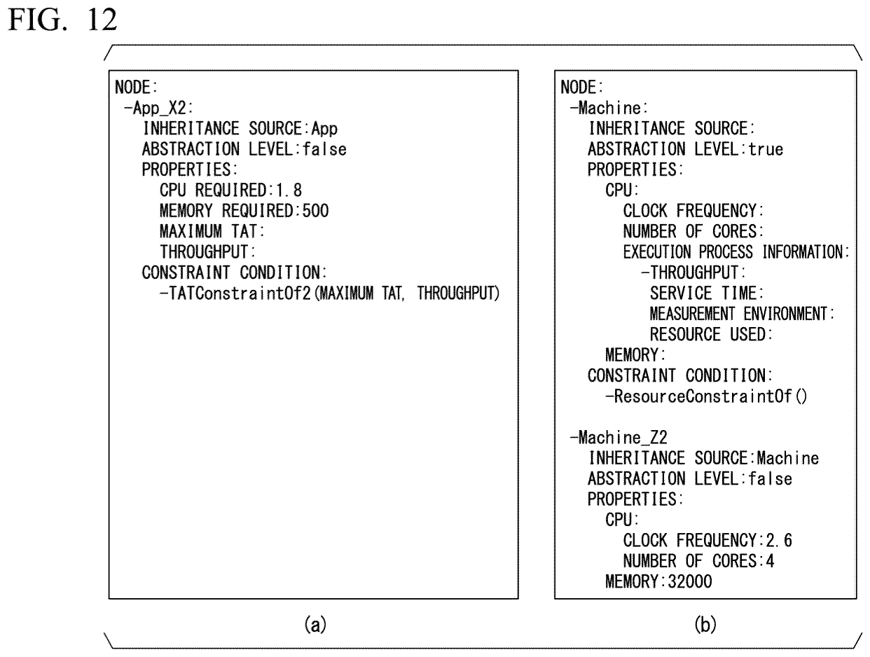

FIG. 12 is a diagram showing an example of definitions of an App_X2 node representing a concrete application, a Machine node representing an abstract machine, and a Machine_Z2 node representing a concrete machine, which are used in the second example embodiment.

In the definition of the App_X2 node, compared to the definition of the App_X node shown in FIG. 5, an additional property representing the expected throughput is indicated. Moreover, in the item “Constraint condition” in the definition of the App_X2 node, the TATConstraintOf2 function, which is a constraint function regarding response time, is indicated. The TATConstraintOf2 function takes the maximum TAT value and the expected throughput as arguments. The TATConstraintOf2 function is a function in which a throughput value is added as an input, as compared with the TATConstraintOf function, which is the constraint function shown in FIG. 5. The TATConstraintOf2 function is a function that outputs a constraint condition for an application represented by the App_X2 node to satisfy a designated maximum TAT value in a state where a load of an expected throughput is applied.

In the Machine node definition shown in FIG. 12, compared to the Machine node definition shown in FIG. 5, a new property “Execution process information” is added. The execution process information is information regarding the processing that uses the resource (the resource for which the execution processing information is indicated). The execution process information includes four types of information: information indicating the throughput representing the load of processing using the resource; information indicating the service time representing the basic performance of the processing using the resource; information indicating the measurement environment of the service time; and information indicating the amount of resources available to the configuration component executing the processing using the resource. The execution process information may be represented in the form of an array.

In a case where multiple processes use the CPU resources of a certain machine, the above four pieces of information about all of those processes are stored in the properties of the execution process information.

Furthermore, in the definition of the Machine node shown in FIG. 12, a constraint function called a ResourceConstraintOf function is indicated as a constraint condition regarding resources. The ResourceConstraintOf function is a constraint function for generating a constraint condition regarding the amount of resources used by each node, which is defined in a concretization rule in the first example embodiment.

The Machine_Z2 node represents a concrete machine that inherits the Machine node mentioned above.

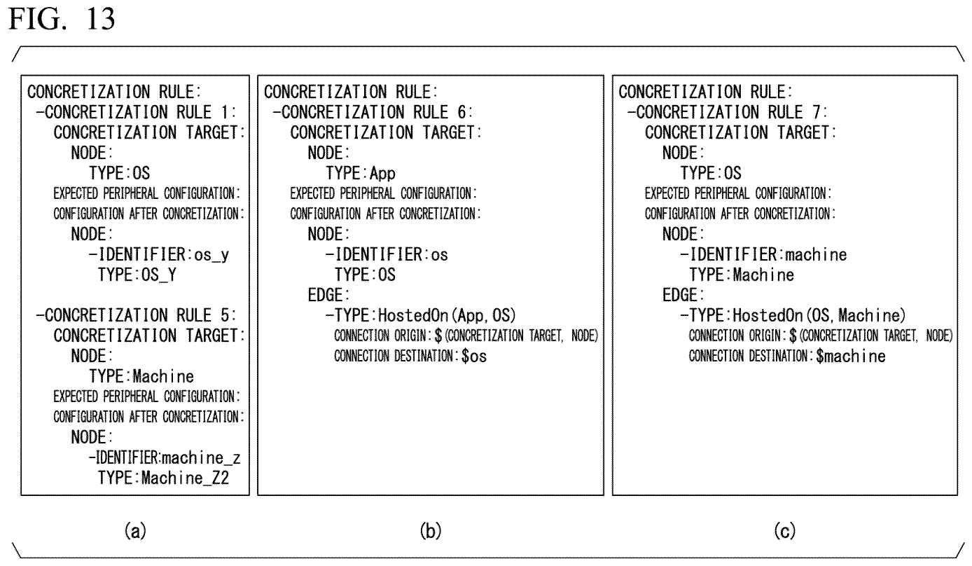

FIG. 13 is a diagram showing an example of definitions of concretization rules used by the system design device 80 in the second example embodiment.

The concretization rule 1 of FIG. 13 is similar to the concretization rule 1 of FIG. 7. The concretization rule 5 of FIG. 13 is a concretization rule for concretizing an abstract Machine node into a concrete Machine_Z2 node.

In the concretization rule 6 of FIG. 13, the item “Constraint condition” is removed from the concretization rule 3 of FIG. 7. Moreover, in the concretization rule 7 of FIG. 13, the item “Constraint condition” is removed from the concretization rule 4 of FIG. 7. The item “Constraint condition” is removed because, as described above, in the second example embodiment, constraint conditions regarding resource usage are generated by the constraint condition generation unit 50, and therefore need not be defined in individual concretization rules.

Next, the processing topology related data used in the second example embodiment will be described. A processing topology is a part of a system configuration, and the method of expressing the configuration components of the processing topology and the concretization rules of the processing topology is similar to the method of expressing the configuration components and the concretization rules described in the first example embodiment.

Here, the process topology is a topology for expressing the process flow of each process and the resources used, and the minimum number of configuration components and concretization rules required to construct a process topology are limited. The following describes the types and definitions of the minimum necessary configuration components and concretization rules required for constructing the processing topology.

However, configuration components of the processing topology and concretization rules for the processing topology may be added as required.

The minimum configuration components that constitute the processing topology are three types: the load generated in each process; the smallest unit of processing executed within the process; and the resources used by the smallest unit of processing. Moreover, the smallest unit of processing is classified into internal processing, which represents the processing of the process itself, and external processing, which calls other processes.

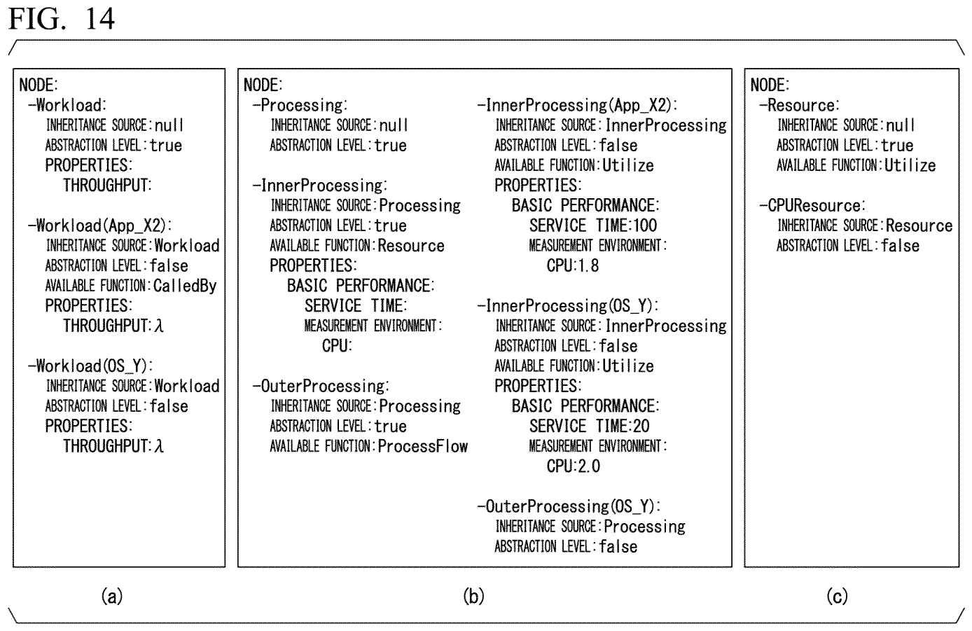

FIG. 14 is a diagram showing an example of definitions of configuration components of a processing topology in the second example embodiment.

(a) of FIG. 14 shows an example of a Workload node definition, which represents the load generated in each process, and sets the expected throughput as a property.

Workload(App_X2) and Workload(OS_Y) are Workload nodes that represent the loads imposed on the App_X2 node and the OS_Y node, respectively, and the property throughput is set to the default value 2. As will be described later, 2 represents the average arrival rate of processing requests in the entire system.

In a case where the expected load value is designated by the user as a system requirement, the Workload(App_X2) node and the Workload(OS_Y) node each use the designated value. On the other hand, if the expected load value is not designated, the Workload(App_X2) node and the Workload(OS_Y) node use this default value.

Furthermore, the Workload(App_X2) node, which is the node of the load imposed on the App_X2 node, has a CalledBy relationship defined as an available function. This means that the App_X2 node is called from another process.

(b) of FIG. 14 shows an example of a definition of a node that represents the smallest unit of processing executed within a process.

An InnerProcessing node (InnerProcessing type node) is a node that represents the internal processing executed by the process itself, and the service time and the measurement environment are set as properties that represent the basic performance of the internal processing.

Also, “Available function: Resource” indicates that resources are required to execute the program.

The service time, which is one of the properties of the internal processing node, is a value having the same meaning as the service time indicated in the properties of the App_X2 node and the OS_Y node in the first example embodiment. In the second example embodiment, the service times of the processes of the App_X2 node and the OS_Y node are not set in the App_X2 node and the OS_Y node themselves, but are set in the InnerProcessing node, which is the smallest unit of processing. By setting and including an arbitrary InnerProcessing node within the processing topology that models the processing of the App_X2 node and the OS_Y node, various processing flows can be represented in the processing topology.

The measurement environment among the properties indicates the actual measurement environment in which the service time is measured. The actual measured value of the service time of each process is greatly affected by the environment in which the service time is measured, for example, the CPU performance of the machine on which the service time is measured. Therefore, in an InnerProcessing type node, the basic performance value of each process is expressed by combining the measurement environment and the service time in that environment.

An OuterProcessing type node is a node that represents an external processing that calls an external program from a processing within a certain process. In (b) of FIG. 14, the InnerProcessing(App_X2) node and the InnerProcessing(OS_Y) node are defined as the smallest unit of internal processing within the processes of the App_X2 node and the OS_Y node. Moreover, an OuterProcessing(OS_Y) node is defined as an external processing in which an OS_Y process (a process of an OS_Y node) calls an external program.

(c) of FIG. 14 shows an example of a definition of a node representing the type of resource used in internal processing. The Resource type shown in (c) of FIG. 14 and the CPUResource node that inherits the Resource type are nodes that designate the type of resource to be used. Therefore, in order to designate a concrete CPU to be used, a relationship is required that utilizes the Machine node that is equipped with the CPU. This is shown by the “Available function: Utilize”.

Next, the relationship regarding the processing topology will be described. There are six types of relationships minimally required to construct the processing topology.

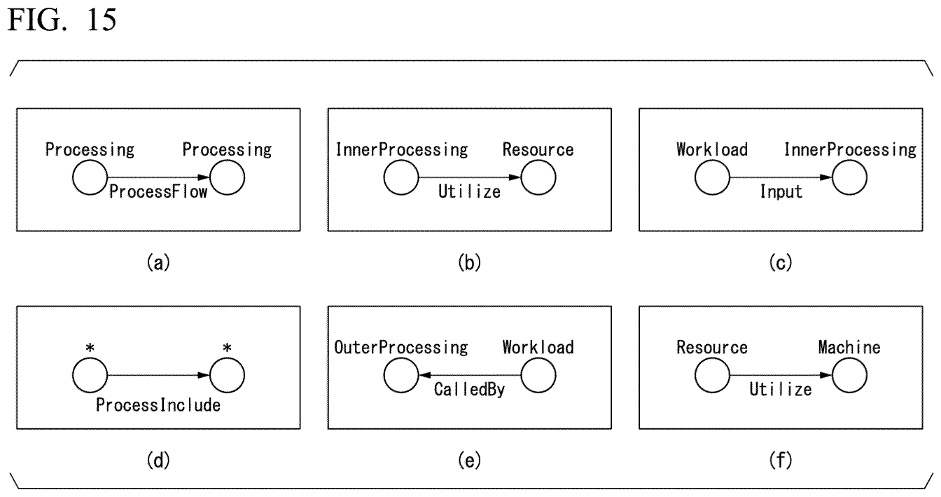

FIG. 15 is a diagram showing an example of the graphical representation of the six types of relationships required to construct the processing topology.

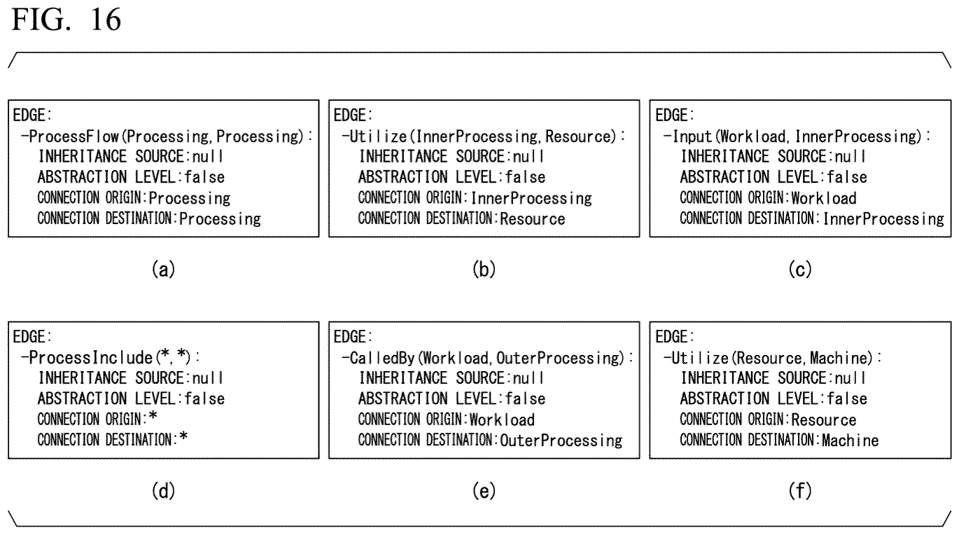

FIG. 16 is a diagram showing an example of the textual representation of the six types of relationships required to construct the processing topology.

The first type of relationship is a relationship that represents the order in which processes are called. In (a) of FIG. 15 and (a) of FIG. 16, the execution of one process followed by another process is represented by an edge called ProcessFlow(Processing, Processing).

The second type of relationship is a relationship that represents the type of resource that an internal process uses. In (b) of FIG. 15 and (b) of FIG. 16, the use of a certain type of resource by internal processing is represented by an edge called Utilize (InnerProcessing, Resource).

The third type of relationship is a relationship that represents the kind of load imposed on the internal processing. In (c) of FIG. 15 and (c) of FIG. 16, the load on the internal processing is represented by an edge called Input (Workload, Inner Processing).

The fourth type of relationship is a relationship that represents which configuration component of the processing topology represents the processing of which configuration component of the configuration topology. In (d) of FIG. 15 and (d) of FIG. 16, an edge called ProcessInclude(*, *) represents that a certain configuration component of the processing topology is included in the processing topology that models the processing executed by a certain configuration component of the configuration topology. Here, “*” indicates that the types of the connection origin node and connection destination node are not limited. For example, the connection origin corresponds to an App node or an OS node, and the connection destination corresponds to a configuration component of the processing topology shown in FIG. 14.

The fifth type of relationship is a relationship that represents that a process is called from another process. In (e) of FIG. 15 and (e) of FIG. 16, the load that occurs in a process is generated by calling external processing of another process, and this is represented by an edge called CalledBy (Workload, OuterProcessing).

The sixth type of relationship is a relationship that designates the concrete resource to be actually used based on the resource type. In (f) of FIG. 15 and (f) of FIG. 16, an edge called Utilize (Resource, Machine) represents the designation of the concrete resource (or the machine that has the resource) to be used depending on the type of the designated resource.

Next, concretization rules for constructing the processing topology will be described. The information that a processing topology can represent is the flow of processes executed by system configuration components such as applications, middleware, and operating system, the process of calling another program within that process, and the concrete resources used by each process.

Here, the processing flow of a process executed by a system configuration component is unique to the configuration component, and can be defined regardless of the system structure. Therefore, concretization rules for concretizing the process topology that represents the processes executed by the respective configuration components are generated in advance. By applying the concretization rules to the process topology during system design, the process topology expressing the processes executed by the respective configuration components is concretized.

On the other hand, the relationships of which external programs are called within a process and which machine resources are used by internal processing within a process cannot be defined prior to designing because these relationships vary depending on the type of software installed in the system configuration components and the type of machine hosting the configuration components on which the processing is executed. Therefore, by generating concretization rules to determine which programs to call and which resources to use depending on the system configuration, and applying these concretization rules to the processing topology during system design, the relationships are dynamically concretized according to the system configuration being designed.

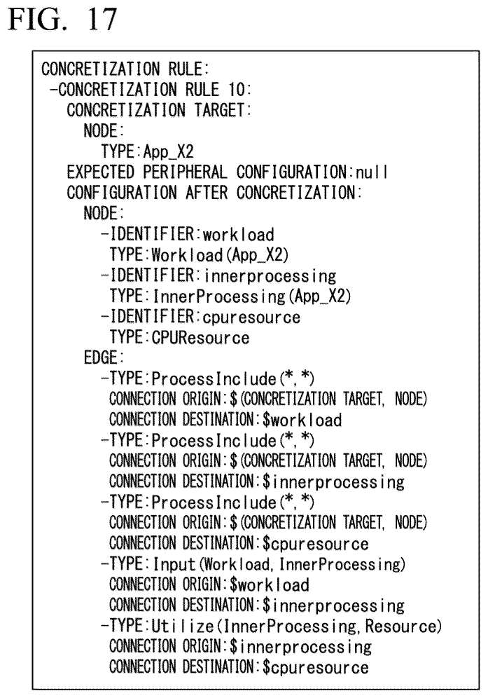

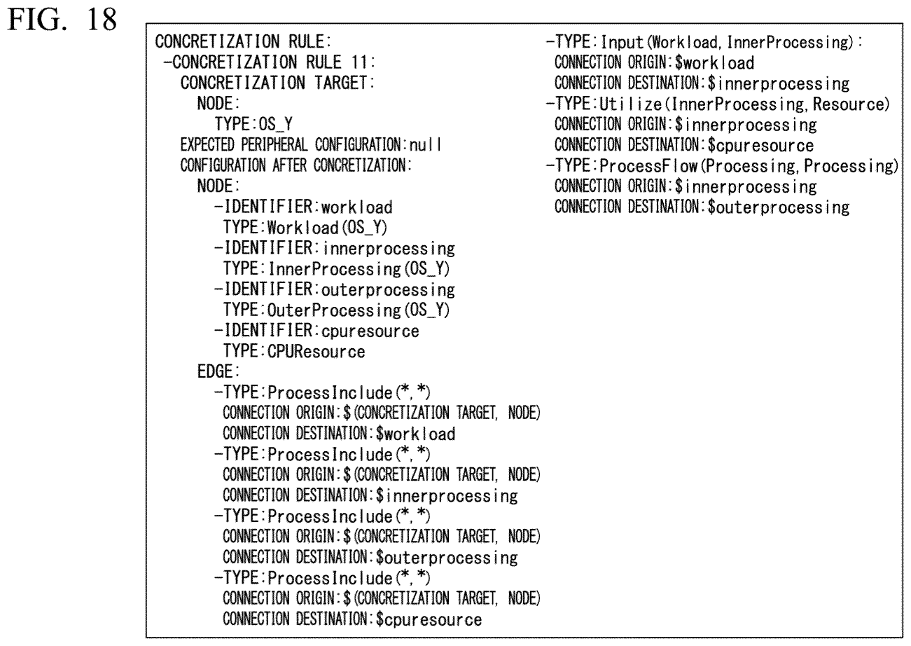

FIG. 17 to FIG. 21 show examples of the definition of concretization rules of a processing topology.

FIG. 17 is a diagram showing a first example of the definition of the concretization rule of the processing topology. FIG. 17 shows an example of the definition of the concretization rule 10.

FIG. 18 is a diagram showing a second example of the definition of the concretization rule of a processing topology. FIG. 18 shows an example of the definition of the concretization rule 11.

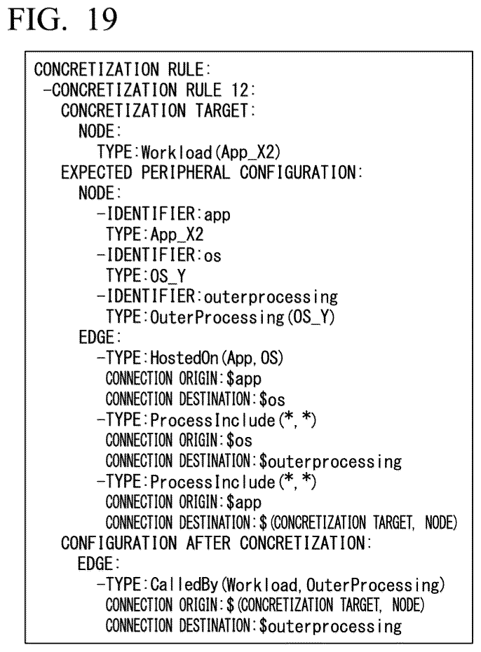

FIG. 19 is a diagram showing a third example of the definition of the concretization rule of a processing topology. FIG. 19 shows an example of the definition of the concretization rule 12.

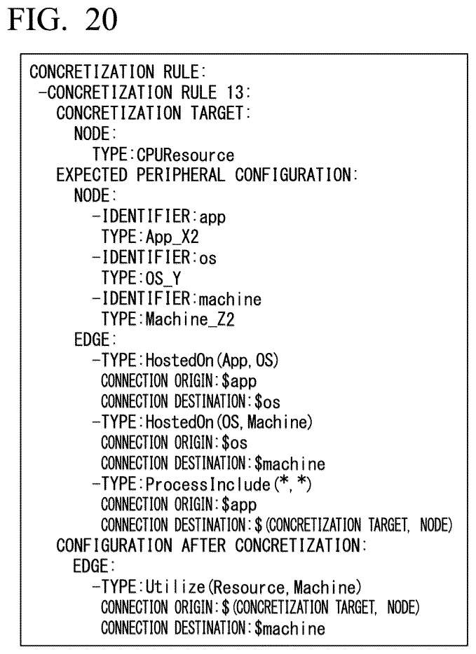

FIG. 20 is a diagram showing a fourth example of the definition of the concretization rule of a processing topology. FIG. 20 shows an example of the definition of the concretization rule 13.

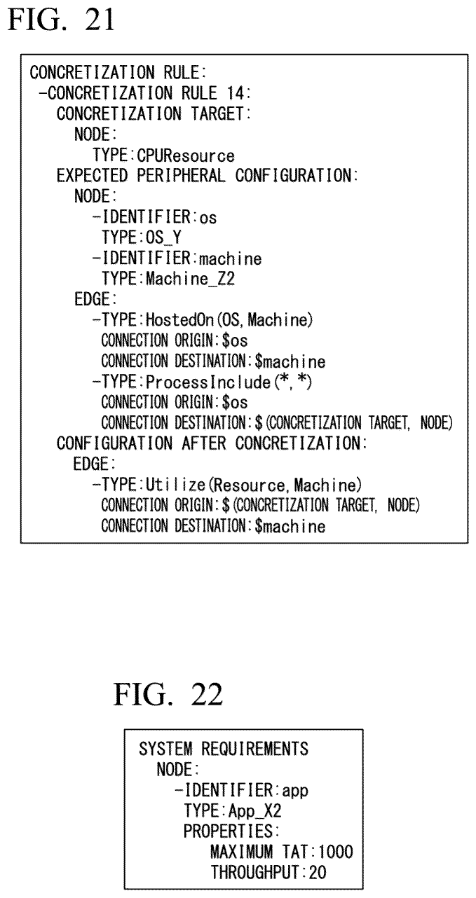

FIG. 21 is a diagram showing a fifth example of the definition of the concretization rule of a processing topology. FIG. 21 shows an example of the definition of the concretization rule 14.

The concretization rules 10 and 11 are concretization rules that construct a process topology that represents the processing within a process executed by the system configuration components.

The concretization rule 10 is a concretization rule that constructs a process topology that represents the processing flow of the process of App_X2. Specifically, the concretization rule 10 constructs a processing topology that represents that if some load occurs, an internal processing that uses CPU resources is executed.

The concretization rule 11 constructs a processing topology that represents the processing flow of the OS_Y process in which, if some load occurs, an internal process that uses CPU resources is executed, and then an external process that calls an external program is executed.

The concretization rule 12 is an example of a concretization rule for a relationship in which the load on a process is generated by a call from another process. In the concretization rule 12, the relationship in which the load imposed on the App_X2 process is generated by a call from the OS_Y process that hosts App_X2, is concretized by extending a CalledBy edge from Workload in the processing topology of App_X2 to OuterProcessing in the processing topology of OS_Y.

The concretization rule 13 is a concretization rule for concretely designating resources to be used in the internal processing of the process of the App_X2 node. The concretization rule 13 concretizes the relationship in which the CPU resources used in the internal processing of the App_X2 node are the CPU resources of the Machine_Z2 node on which the App_X2 node and the OS_Y node hosting the App_X2 node are installed.

The concretization rule 14 is a concretization rule for concretely designating resources to be used in the internal processing of the process of the OS_Y node. The concretization rule 14 concretizes the relationship in which the CPU resource used in the internal processing of the OS_Y node is the CPU resource of the Machine_Z2 node in which the OS_Y node is installed.

Next, an example of the definition of system requirements in the second example embodiment will be described.

FIG. 22 is a diagram showing an example of the definition of system requirements in the second example embodiment.

In the system requirements shown in FIG. 22, throughput is added as an additional property, compared to the system requirements shown in FIG. 4. The system requirements shown in FIG. 22 indicate a requirement that the TAT value indicated in the property be satisfied in the throughput environment indicated in the property.

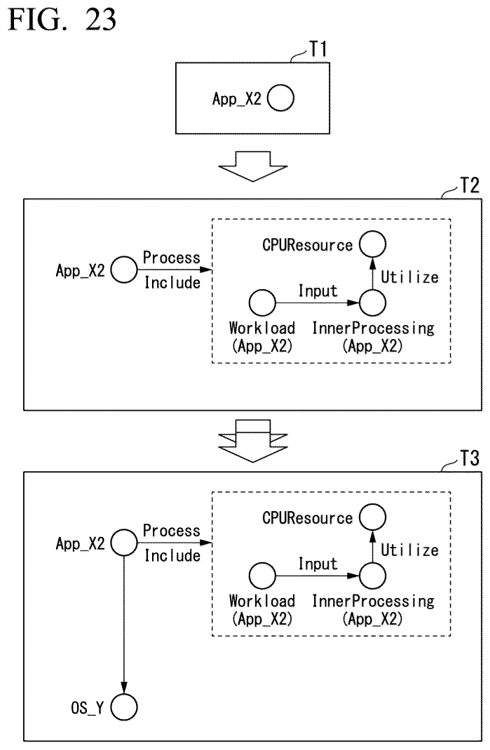

In a case where the system requirements shown in FIG. 22 are given, examples of concretizing a system configuration using the configuration components and concretization rules defined in FIG. 5, FIG. 6, FIG. 12 to FIG. 14, FIG. 16, and FIG. 17 to FIG. 21 are shown in FIG. 23 to FIG. 28.

FIG. 23 is a diagram showing a first example of concretization of the system configuration in the second example embodiment.

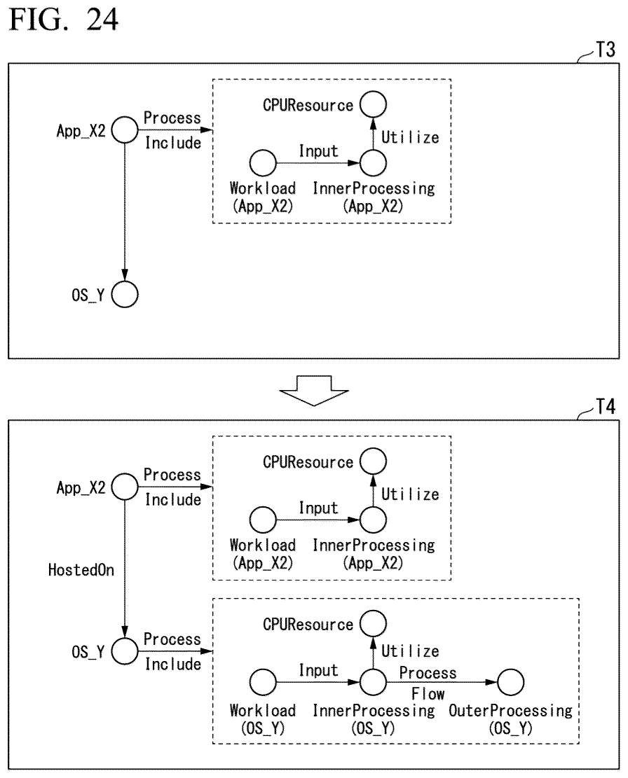

FIG. 24 is a diagram showing a second example of concretization of the system configuration in the second example embodiment. FIG. 24 shows an example of the concretization performed by the system design device 80 after the concretization of FIG. 23.

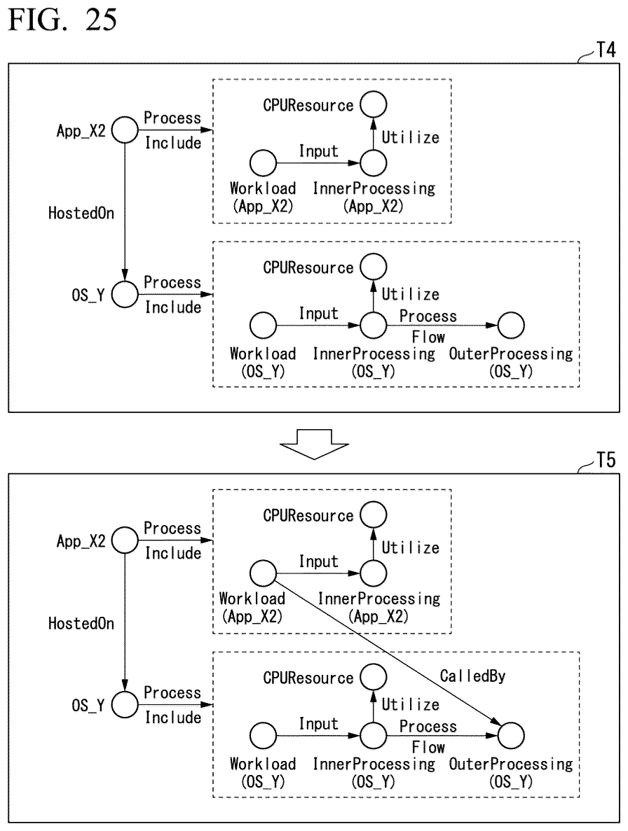

FIG. 25 is a diagram showing a third example of concretization of the system configuration in the second example embodiment. FIG. 25 shows an example of the concretization performed by the system design device 80 after the concretization of FIG. 24.

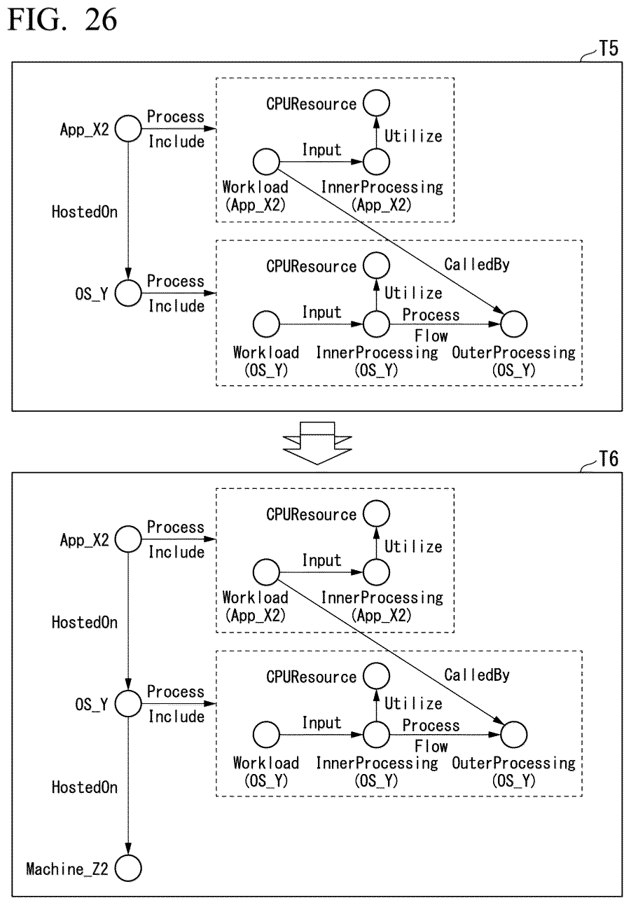

FIG. 26 is a diagram showing a fourth example of concretization of the system configuration in the second example embodiment. FIG. 26 shows an example of the concretization performed by the system design device 80 after the concretization of FIG. 25.

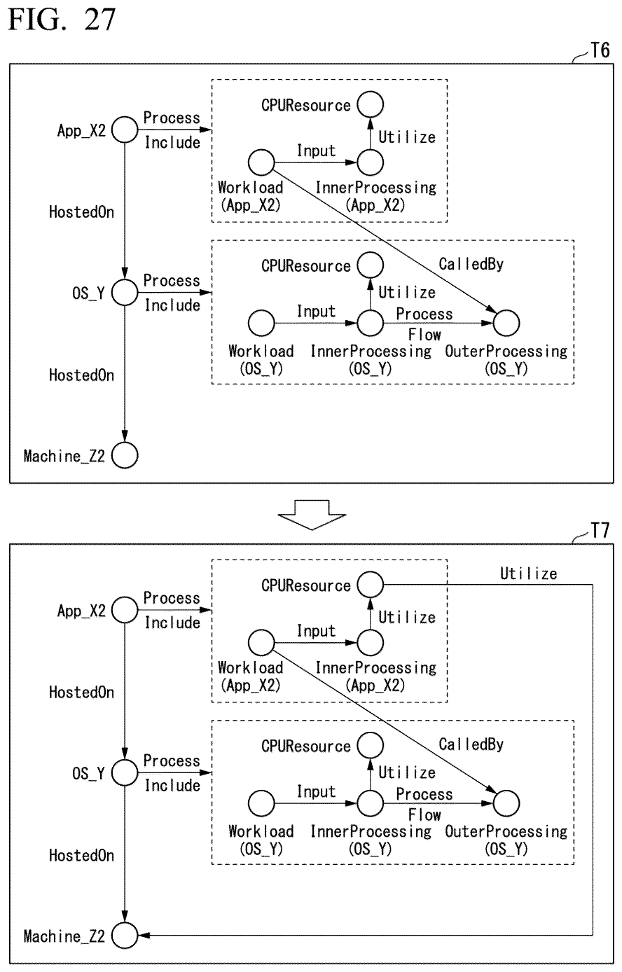

FIG. 27 is a diagram showing a fifth example of concretization of the system configuration in the second example embodiment. FIG. 27 shows an example of the concretization performed by the system design device 80 after the concretization of FIG.

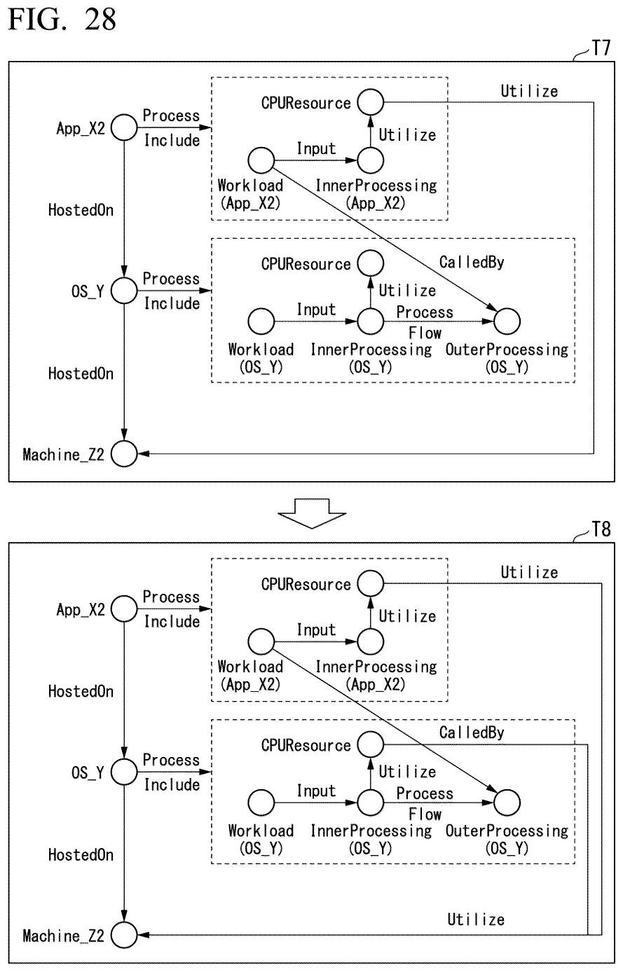

FIG. 28 is a diagram showing a sixth example of concretization of the system configuration in the second example embodiment. FIG. 28 shows an example of the concretization performed by the system design device 80 after the concretization of FIG. 27.

A system requirement T1 of FIG. 23 shows the system requirement of FIG. 22.

In a case where the system requirement T1 is given as an input, the system design device 80 applies the concretization rule 10 to the system requirement T1. As a result, the system design device 80 acquires a system configuration T2 in which a processing topology representing the processing of the App_X2 node is concretized.

In the system configurations shown in FIG. 23 to FIG. 28, the portions enclosed by dashed lines correspond to examples of processing topologies. In the system configurations, the portions other than the portions enclosed by the dashed lines correspond to examples of configuration topologies.

In the system configurations shown in FIG. 23 to FIG. 28, a ProcessInclude edge extending from a node to a dashed square means that a ProcessInclude edge extends to all nodes contained within the dashed square.

Next, the system design device 80 applies to the system configuration T2 the concretization rules for generating an OS node and concretizing it to an OS_Y node shown in FIG. 13, thereby acquiring a system configuration T3.

In the examples of FIG. 23 to FIG. 28, two overlapping arrows indicate the application of multiple concretization rules.

Next, the system design device 80 applies the concretization rule 11 to the system configuration T3 to thereby acquire a system configuration T4 in which the processing topology of the OS_X node is concretized.

Next, the system design device 80 applies the concretization rule 12 to the system configuration T4 to thereby acquire a system configuration T5 in which the relationship that the process of the App_X2 node is called from the processing of the OS_Y node is concretized.

Next, the system design device 80 applies to the system configuration T5 the concretization rules for generating a Machine node and concretizing it to a Machine_Z2 node shown in FIG. 13, thereby acquiring a system configuration T6.

Next, the system design device 80 applies the concretization rule 13 to the system configuration T6 to thereby acquire a system configuration T7 in which the Machine_Z2 node hosting the App_X2 node is designated as the CPU resource to be used by the internal processing of the App_X2 node.

Furthermore, the system design device 80 applies the concretization rule 14 to the system configuration T7 to thereby obtain a system configuration T8 in which the Machine_Z2 node hosting the OS_Y node is designated as the CPU resource to be used by the internal processing of the OS_Y node.

Here, the concretization of the system configuration does not necessarily require the concretization rules to be applied in the order shown in FIG. 23 to FIG. 28. If there are multiple concretization rules applicable to a certain system configuration, any of the multiple concretization rules can be applied first. For example, the system design device 80 may apply a concretization rule for concretizing the OS_Y node or a concretization rule for concretizing the Machine_Z2 node before applying the concretization rule 10 from the state of the system requirement T1 shown in FIG. 23.

If there are multiple applicable concretization rules, the method by which the system design device 80 selects a concretization rule to be applied is not limited to a particular method. For example, the system design device 80 may randomly select one of the multiple concretization rules. Alternatively, the system design device 80 may select one of the multiple concretization rules, based on the results of machine learning.

Next, constraint functions in the second example embodiment will be described. As examples of the constraint functions in the second example embodiment, specific examples of a constraint function (TATConstraintOf2) that generates a constraint condition regarding a response time, and a constraint function (ResourceConstraintOf) that generates a constraint condition regarding a resource usage will be shown. These constraint functions generate constraint conditions based on the system configuration, including the processing topology.

However, the constraint functions used by the system design device 80 are not limited to these functions. The user can edit constraint functions via the constraint function registration unit 70.

The TATConstraintOf2 function takes the maximum TAT value and the throughput value as input, and generates and returns a constraint condition on the response time that the system must satisfy. The configuration search means included in the TATConstraintOf2 function searches the system structure including the processing topology, and extracts the path of the InnerProcessing node, which is a configuration component representing the processing in the system configuration, as a node that affects the TAT requirement.

The InnerProcessing node is an example of a node that represents a process. The configuration search means of the TATConstraintOf2 function corresponds to an example of a process extraction method shown in the constraint function.

Specifically, the constraint condition generation unit 50 executes the configuration search means.

The constraint condition generation unit 50 starts from a configuration component in the system configuration for which the TATConstraintOf2 function is set, and extracts an inner process (InnerProcessing node) from the processing topology representing the process of the configuration component. Moreover, the constraint condition generation unit 50 sets the throughput value given as an input to the TATConstraintOf2 function, to the throughput property of the Workload node from which an edge extends to the extracted internal processing node.

Thereafter, the constraint condition generation unit 50 determines whether the processing of the target configuration component is called from a process of another configuration component. In other words, the constraint condition generation unit 50 determines whether a CalledBy edge extends from the Workload node in the processing topology of the target configuration component, to the OuterProcessing node in the processing topology of another configuration component. If it is determined that the calling configuration component is present, the constraint condition generation unit 50 selects the calling configuration component and returns to the initial process. On the other hand, if it is determined that the calling configuration component is not present, the constraint condition generation unit 50 outputs a path including the InnerProcessing nodes extracted up to that point, and ends the processing as the configuration search means.

The path of the nodes referred to here can be defined as a set including nodes as its elements. The InnerProcessing nodes corresponds to an example of nodes indicating processes, and the path of the InnerProcessing nodes corresponds to an example of a process group.

The constraint generation means included in the TATConstraintOf2 function generates a constraint condition to be satisfied over the entire path, based on the path information output by the configuration search means.

Specifically, the constraint condition generation unit 50 executes the constraint generation means.

The constraint condition generation unit 50 generates a constraint condition such that the sum of the execution times of the processes represented by the InnerProcessing nodes on the path output by the processing as the configuration search means, is less than or equal to the maximum TAT value given as an input to the TATConstraintOf2 function. The constraint condition generation unit 50 then returns all the constraint conditions generated by executing the constraint generation means, as the output of the TATConstraintOf2 function.

The ResourceConstraintOf function generates and returns a constraint condition on resource usage that a resource must satisfy. The ResourceConstraintOf function has two configuration search means. A first configuration search means extracts all configuration components hosted by configuration components designated with the ResourceConstraintOf function.

Specifically, the constraint condition generation unit 50 executes the first configuration search means. The constraint condition generation unit 50 searches the system configuration and extracts the configuration components for which the ResourceConstraintOf function is designated and the connection origin node connected by a HostedOn edge. Thereafter, the constraint condition generation unit 50 treats the extracted connection origin node as a new target, and extracts the connection origin node connected to this node by a HostedOn edge. The constraint condition generation unit 50 repeats this process until no nodes that satisfy the condition remain.

A second configuration search means adds the following four pieces of information related to all processes that use the resource of the configuration component for which the ResourceConstraintOf function is designated, to the properties of the resource in the configuration component.

Specifically, the constraint condition generation unit 50 executes the second configuration search means. The constraint condition generation unit 50 searches the system configuration including the processing topology, and follows the Resource node with a Utilize edge extending to the configuration component for which the ResourceConstraintOf function is designated, and the InnerProcessing node with a Utilize edge extending to the Resource node.

Then, the constraint condition generation unit 50 adds the value of the service time and the value of the measurement environment, which are properties of the InnerProcessing node, to the properties of the Resource node. Furthermore, the constraint condition generation unit 50 adds an id designating the “CPU used” property defined in the configuration component that has a ProcessInclude edge extending to the InnerProcessing node, and an id designating the throughput property defined in the Workload node that has an Input edge extending to the InnerProcessing node, to the “throughput” and “resource usage” properties of the resource.

Here, the reason for storing variables that hold values instead of the values themselves in the latter two properties is that, at that point, these two properties may not have concrete values, and there is a possibility that the values may be updated by other processes.

If a single resource is used by multiple processes, that is, if there are multiple Resource nodes with a Utilize edge extending to a certain Machine node, the constraint condition generation unit 50 executes this process for all of those Resource nodes. The constraint condition generation unit 50 then outputs all the nodes extracted by the first configuration search means.

The ResourceConstraintOf function also has two constraint generation means. The first constraint generation means generates a constraint condition regarding the amount of a resource used by a configuration component for which the ResourceConstraintOf function is designated.

Specifically, the constraint condition generation unit 50 executes the first constraint generation means.

The constraint condition generation unit 50 generates a constraint condition on CPU resources for all nodes output by executing the configuration search means, such that the value of the CPU clock frequency property of the configuration component for which the ResourceConstraintOf function is designated is greater than or equal to the value of the “CPU used” property set for each of those nodes. Moreover, the constraint condition generation unit 50 generates a constraint condition on memory resources, such that the value of the “Memory” property of the configuration component is greater than or equal to the sum of the values of the “Memory used” property that are set for each of the nodes.

The second constraint generation means generates a constraint condition regarding the execution time of a process that uses a resource included in a configuration component for which the ResourceConstraintOf function is designated. Specifically, the constraint condition generation unit 50 executes the second constraint generation means.

Two methods for generating constraint conditions on the execution time of processing are given as examples: a generation method that uses a queueing model to estimate performance more accurately; and a generation method that uses a simple expression to approximately estimate performance. In the following, the former is referred to as a constraint condition generation method example 1, and the latter is referred to as a constraint condition generation method example 2.

While the constraint condition generation method example 1 allows for the design of a system with high performance accuracy, application of such a method may be difficult because it is difficult to derive values that satisfy the constraint conditions or it takes a long time to derive the values. Therefore, the constraint condition generation unit 50 selects an appropriate method depending on the situation.

In the constraint condition generation method example 1, the constraint condition generation unit 50 generates a constraint condition such that the execution time of each process using a resource that is the calculation target of the ResourceConstraintOf function, is equal to or greater than the sum of the service time of each process and the process wait time for that resource.

The service time and process wait time of each process are derived by the constraint condition generation unit 50 based on the four types of information added to the execution process information property of the machine node by executing the configuration search means.

In the constraint condition generation method example 1, the service time of each process can be derived using Expression (1).

$$[ Expression 1 ]$$

$$Process service time = Basic process performance . Service time \times \frac{Basic process performance . Measurement environmen𝔱 . CPU}{Configuration component . CPU available} \qquad ( 1 )$$

$$“ \times ” represents multiplication .$$

Based on Expression (1), the constraint condition generation unit 50 derives the service time of a certain process by multiplying the service time set as a property of the InnerProcessing node representing the process, by the ratio obtained by dividing the value of the property “Basic process performance. Measurement environment.CPU”, which represents the CPU environment in which the service time is measured, by the value of the property “Configuration component.CPU available”, which represents the CPU that can be used by the configuration component that executes the process in the system configuration being designed.

Expression (1) indicates that the service time will be shorter if the specifications of the CPU that the target configuration component can use in the system configuration being designed are higher than the CPU used to measure the service time. That is to say, the “Configuration component” in Expression (1) represents the configuration component that executes the process for which the service time is to be calculated.

The constraint condition generation unit 50 derives the process wait time using the queuing theory, based on the service time values of multiple processes sharing the same resource and the throughput values representing the loads imposed on these processes. For example, Expression (2) can be used to derive the process wait time in a case where two processes share one CPU.

$$[ Expression 2 ]$$

$$Process wait time = {f}_{MMS} ( λ , {T}_{s} ) = \frac{1}{λ} \{ \frac{{ρ ( sp )}^{2}}{s ! 1 - {ρ}^{2}} \} \times \{ \frac{1}{{\sum }_{n = 0}^{s - 1} \frac{s {ρ}^{n}}{n !} + \frac{s {ρ}^{s}}{s ! ( 1 - ρ )}} \} \qquad ( 2 )$$

λ represents the average arrival rate of process requests in the entire system. The sum of the throughputs of the two processes can be used as λ. In other words, it can be expressed as “average arrival rate 2 of the entire system=throughput of process 1+throughput of process 2”.

Ts represents the average service time of the entire system. Ts can be represented by the M/M/s queuing model, which is the weighted average of the throughput of each process applied to the service time of each process obtained by Expression (1).

s represents the number of resources. In the case of a CUP resource, s represents the number of cores of the CPU.

For example, Ts can be expressed as Expression (3) according to the wait time derivation formula in the M/M/s model.

$$[ Expression 3 ]$$

$${T}_{s} = \frac{\begin{matrix}Throughput of process 1 \times Service time of process 1 + \\ Throughput of process 2 \times Service time of process 2\end{matrix}}{λ} \qquad ( 3 )$$

ρ is expressed as in Expression (4).

$$[ Expression 4 ]$$

$$ρ = \frac{λ}{s μ} = \frac{λ {T}_{S}}{s} \qquad ( 4 )$$

If the system configuration contains internal processes that use different resources, the constraint condition generation unit 50 calculates the service time and wait time of the process for each resource, and calculates the service time and wait time of all the processes contained in the system configuration.

Thereafter, the constraint condition generation unit 50 generates, for each process, a constraint condition such that the execution time of the process is equal to or greater than the sum of the derived service time and the process wait time.

In the constraint condition generation method example 2, the constraint condition generation unit 50 estimates the execution time taking into consideration the ratio of the CPU that each process can use.

In the constraint condition generation method example 2, the service time of each process can be derived using Expression (5).

$$[ Expression 5 ]$$

$$Execution time of process ( on query path X ) = Service time of process ( on query path X ) \times \frac{{\sum }_{i = 1}^{n} \{ \begin{matrix}Sum of service times for processes on query path i \times \\ Arrival rate of query i\end{matrix} \}}{\begin{matrix}Sum of service times for processes on query path X \times \\ Arrival rate of query X\end{matrix}} \qquad ( 5 )$$

Based on Expression (5), the constraint condition generation unit 50 estimates the execution time of each process by multiplying the service time of the process by the inverse of the ratio of the CPU that can be used by a query (process request) that includes the process.

The method for deriving the service time of each process is the same as the method of deriving the service time in the constraint condition generation method example 1.

The ratio of CPU that a query can use is considered to be 100% if the query is the only one using the CPU. On the other hand, if multiple types of queries share a CPU, the constraint condition generation unit 50 calculates how many seconds in one second each query uses the CPU from the sum of the arrival rate of each query and the service time of the process corresponding to the query, and determines the ratio of the value of the CPU usage time of the target query to the total value of the CPU usage time of all queries.

The constraint condition generation unit 50 executes the constraint generation means to generate a constraint condition for all processes that use the resources of the configuration components for which the ResourceConstraintOf function is designated. The constraint condition generation unit 50 then returns all the generated constraint conditions to the system design unit 20 as an output of the ResourceConstraintOf function.

Next, a process flow in which the constraint condition generation unit 50 of the second example embodiment outputs constraint conditions that must be satisfied by a system configuration will be described, using an example in which constraint conditions that must be satisfied by the system configuration T8 in FIG. 28 are generated.

First, the process flow in which the constraint condition generation unit generates constraint conditions in the second example embodiment will be described.

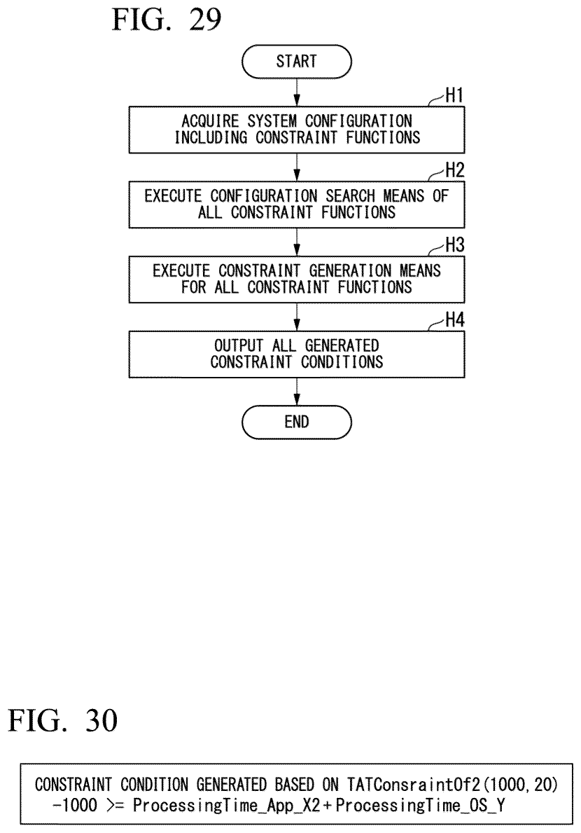

FIG. 29 is a flowchart showing an example of the processing procedure in which the constraint condition generation unit 50 generates constraint conditions. The constraint condition generation unit 50 acquires the system configuration T8 of FIG. 28 from the system design unit 20 in the form of system configuration information (Step H1).

In the system configuration T8, a constraint function regarding response time called TATConstraintOf (1000, 20) is set for the App_X2 node. Moreover, in the system configuration T8, a constraint condition on resource usage called ResourceConstraintOf( ) is set for the Machine_Z2 node.

The constraint condition generation unit 50, which has acquired the system configuration T8 including the constraint function, executes a configuration search means for the TATConstraintOf (1000, 20) function and a configuration search means for the ResourceConstraintOf( ) function (Step H2).

In executing the configuration search means for the TATConstraintOf (1000, 20) function, the constraint condition generation unit 50 sets the App_X2 node as the starting point of the processing, and extracts the InnerProcessing(App_X2) node that represents the internal processing of this node. Moreover, the constraint condition generation unit 50 sets 20 to the “throughput” property of the Workload(App_X2) node, which indicates the load imposed on this internal processing.

The constraint condition generation unit 50 then follows the OuterProcessing node to which a CalledBy edge extends from Workload in the processing topology of App_X2, and sets the OS_Y node as a new target node. Thereafter, the constraint condition generation unit 50 similarly extracts an InnerProcessing(OS_Y) node representing the internal processing of OS_Y, and sets 20 to the “throughput” property of the Workload(OS_Y) node.

The constraint condition generation unit 50, in executing the configuration search means of the TATConstraintOf2 (1000, 20) function, then outputs a path including the InnerProcessing(App_X2) node and the InnerProcessing(OS_Y) node.

In executing the configuration search means of the ResourceConstraintOf( ) function, the constraint condition generation unit 50, starting from a Machine_Z2 node, extracts two nodes, the OS_Y node connected to the node by a HostedOn edge, and the App_X2 node connected to the OS_Y node by a HostedOn edge.

Furthermore, the constraint condition generation unit 50 refers to the InnerProcessing(App_X2) node as a CPUResource node having a Utilize edge extending to the Machine_Z2 designated with the ResourceConstraintOf( ) function, and as a InnerProcessing node having a Utilize edge extending to the CPUResource node.

The constraint condition generation unit 50 then generates the following as information on the processing of the InnerProcessing(App_X2) node.
Service time of node InnerProcessing(App_X2): 100
Service time measurement environment value: 1.8
$Workload(App_X2). Throughput, which designates the “throughput” property of the Workload(App_X2) node having an Input edge extending to the InnerProcessing(App_X2) node
$App_X2.CPU used designating the “CPU Used” property of the App_X2 node, which is the configuration component that executes the processing of the InnerProcessing(App_X2) node
The above four values are added to the execution process information property of the Machine_Z2 node.

Similarly, the constraint condition generation unit 50 generates the following as process information for the InnerProcessing(OS_Y) node, which is another process that uses the Machine_Z2 node.
Service time of node InnerProcessing(OS_Y): 20
Service time measurement environment value: 2.0
$Workload(OS_Y). Throughput, which designates the “throughput” property of the Workload(OS_Y) node having an Input edge extending to the InnerProcessing(OS_Y) node
$OS_Y.CPU used designating the “CPU Used” property of the App_X2 node, which is the configuration component that executes the processing of the InnerProcessing(OS_Y) node
The above four values are also added to the execution process information property of the Machine_Z2 node.

Then, the constraint condition generation unit 50 outputs the two nodes, the App_X2 node and the OS_Y node, extracted in the execution of the first configuration search means.

Next, the constraint condition generation unit 50 executes the constraint generation means of the TATConstraintOf (1000, 20) function and the constraint generation means of the ResourceConstraintOf( ) function (Step H3).

In executing the constraint generation means of the TATConstraintOf (1000, 20) function, the constraint condition generation unit 50 generates a constraint condition “1000>=ProcessingTime_App_X2+ProcessingTime_OS_Y”, which indicates the condition such that the sum of the execution times of the processing represented by the InnerProcessing nodes on the path extracted by executing the configuration search means must be less than or equal to the maximum TAT of 1000.

Here, ProcessingTime_App_X2 and ProcessingTime_OS_Y are variables that represent the execution times of the processes represented by the InnerProcessing(App_X2) node and the InnerProcessing(OS_Y) node, respectively.

In executing the constraint generation means of the ResourceConstraintOf( ) function, the constraint condition generation unit 50 generates three constraints, “2.6>=App_X2.CPU used”, “2.6>=OS_Y.CPU used”, and “32000>=App_X2.Memory used+OS_Y.Memory used”, based on the resource usage of the App_X2 node and the OS_Y node extracted by executing the configuration search means and on the resources installed in Machine_Z2.

Furthermore, the constraint condition generation unit 50 generates constraint conditions on the execution times of the processes represented by the InnerProcessing(App_X2) node and the InnerProcessing(OS_Y) node, based on the information stored in the execution process information property of the Machine_Z2 node.

In the case of using the constraint condition generation example 1, the constraint condition generation unit 50 derives the service time Ts(App_X2) of the processing represented by the InnerProcessing(App_X2) node based on Expression (1) as Ts(App_X2)=100×(1.8/App_X2.CPU used). Here, “/” represents division. Furthermore, the constraint condition generation unit 50 derives the service time Ts(OS_Y) of the processing represented by the InnerProcessing(OS_Y) node as Ts(OS_Y)=20×(2.0/OS_Y.CPU used).

Moreover, the CPU resources of the Machine_Z2 node are shared by two processes: the process of the App_X2 node, which has a throughput of 20 and a service time of Ts(App_X2), and the process of the OS_Y node, which has a throughput of 20 and a service time of Ts(OS_Y). From this, the constraint condition generation unit 50 can derive the average arrival rate of the entire system to be 40, and the average service time of the entire system to be the wait time in the M/M/4 queuing model of {20×Ts(App_X2)+20×Ts(OS_Y)}/40.

Where the wait time derived by this expression is represented as Tw, the constraint condition generation unit 50 generates two constraint conditions on the execution time of each process, namely, “ProcessingTime_App_X2>=Ts(App_X2)+Tw” and “ProcessingTime_OS_Y>=Ts(OS_Y)+Tw”. Thereafter, the constraint condition generation unit 50 outputs a total of five constraint conditions generated by executing the constraint generation means of the ResourceConstraintOf( ) function.

In the case of using the generation condition generation example 2, the constraint condition generation unit 50 estimates the execution time of the App_X2 node as the service time derived by Expression (1) multiplied by the inverse of the ratio at which the query including the App_X2 node can use the CPU. In the examples of FIG. 23 to FIG. 28, there is only one type of query that includes the processing of the App_X2 node and the OS_Y node. From this, the constraint condition generation unit 50 calculates the ratio of the CPU that the query including the App_X2 node can use, based on the second term on the right-hand side of Expression (5) as {(20+100)×20}/{(20+100)×20}=1. The constraint condition generation unit 50 similarly derives the execution time for the processing of the OS_Y node.

The constraint condition generation unit 50 then generates two constraint conditions, namely, “ProcessingTime_App_X2>=Ts(App_X2)×1”, and “ProcessingTime_OS_Y>=Ts(OS_Y)×1”. Thereafter, the constraint condition generation unit 50 outputs a total of five constraint conditions generated by the constraint generation means of the ResourceConstraintOf( ) function.

After Step H4, the constraint condition generation unit 50 ends the processing of FIG. 29.

In the above example, the constraint conditions generated by the constraint condition generation unit 50 based on the TATConstraintOf2 (1000, 20) function and the ResourceConstraintOf( ) function are summarized in FIG. 30 to FIG. 32.

FIG. 30 is a diagram showing an example of a constraint condition generated by the constraint condition generation unit 50, based on the TATConstraintOf2 (1000, 20) function.

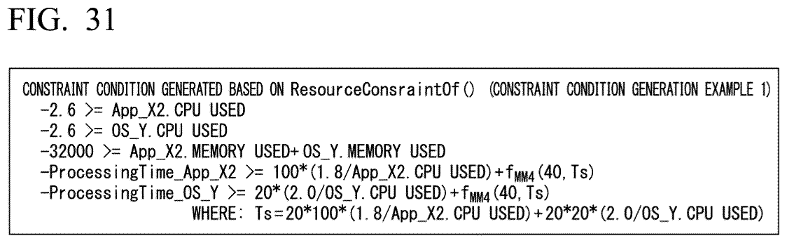

FIG. 31 is a diagram showing an example of a constraint condition generated by the constraint condition generation unit 50, based on the ResourceConstraintOf( ) function by using the constraint condition generation example 1.

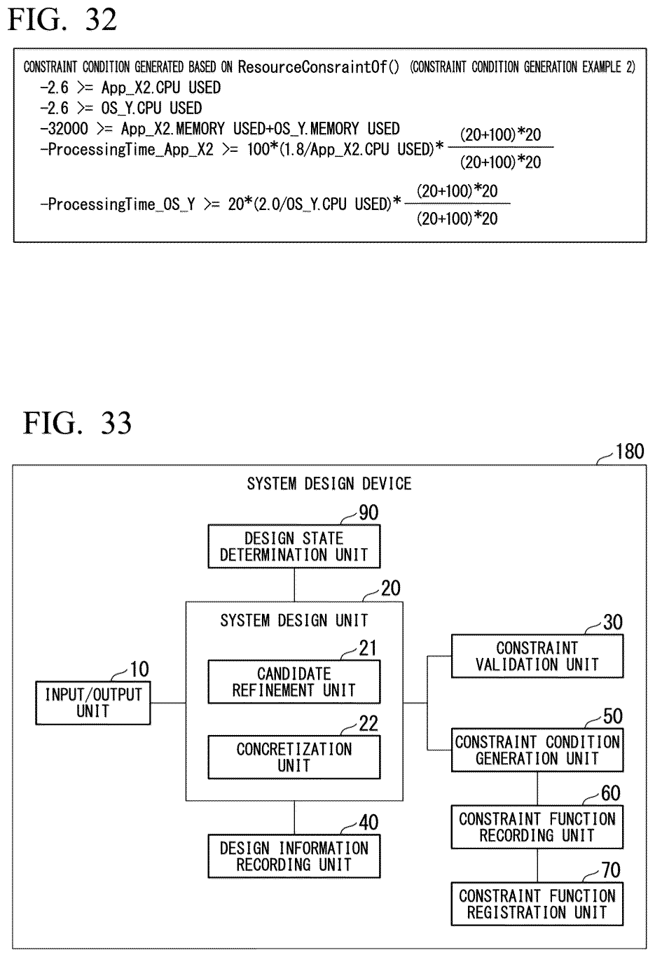

FIG. 32 is a diagram showing an example of a constraint condition generated by the constraint condition generation unit 50, based on the ResourceConstraintOf( ) function by using the constraint condition generation example 2.

### DESCRIPTION OF EFFECT

The system design device 80 according to the second example embodiment generates constraint conditions related to response times that the system must satisfy, based on a process topology that models the processes to be executed, and the amount of resources available to each process.

As a result, according to the system design device 80 of the second example embodiment, it is possible to design a high-quality system that satisfies requirements regarding response times with a higher degree of accuracy.

As described above, the system configuration information includes a model indicating a configuration of a process executed by the system configuration. The constraint condition generation unit 50 generates a constraint condition related to the process, based on the model indicating a configuration of the process.

According to the system design device 80, it is possible to generate constraint conditions for processes executed by a target system configuration, and determine whether or not the target system configuration satisfies the constraint conditions.

In this respect, according to the system design device 80, it is possible to design a system that satisfies process-related constraint conditions desired by the user.

Moreover, according to the system design device 80, it is possible to exclude system configurations that cannot satisfy process-related constraint conditions from candidates for system design, and in this respect, this enables efficient system design.

Furthermore, the system configuration information includes information on a processing time for each of the processes. The constraint condition generation unit 50 extracts a process group constituting a series of processing executed by a predetermined process call designated in the system configuration information based on a process extraction method indicated in the constraint function, and generates a constraint condition such that a total processing time of each process included in the process group extracted is within an allowable time range designated for the process call.

According to the system design device 80, it is possible to generate constraint conditions regarding process processing times and determine whether or not a target system configuration satisfies the constraint conditions regarding process processing times. In this respect, according to the system design device 80, it is possible to design a system desired by the user.

Moreover, the system configuration information includes information on a computational resource usage for each of the processes. The constraint condition generation unit 50 extracts a process group that utilizes a predetermined computational resource indicated in the system configuration information based on a process extraction method indicated in the constraint function, and generates a constraint condition such that a total amount of computational resources required for each process included in the extracted process group to perform processing in a service time and at a processing request arrival rate designated for that process, for the process group, is within a range of an amount of computational resources that can be provided by the computational resources.

According to the system design device 80, it is possible to generate constraint conditions regarding the use of computational resources by processes, and determine whether or not a target system configuration satisfies the constraint conditions regarding the use of computational resources by processes. In this respect, according to the system design device 80, it is possible to design a system desired by the user.

### Third Example Embodiment

### (Description of Configuration)

Next, a system design device according to a third example embodiment will be described.

FIG. 33 is a block diagram showing a configuration example of a system design device according to the third example embodiment. In the configuration shown in FIG. 33, a system design device 180 includes an input/output unit 10, a system design unit 20, a constraint validation unit 30, a design information recording unit 40, a constraint condition generation unit 50, a constraint function recording unit 60, a constraint function registration unit 70, and a design state determination unit 90.

Of the constituents shown in FIG. 33, ones corresponding to those in FIG. 1 are given the same reference symbols (10, 20, 30, 40, 50, 60, and 70), and descriptions thereof are omitted.

The system design device 180 further includes the design state determination unit 90 in addition to the units included in the system design device 80 of FIG. 1. In other respects, the system design device 180 is similar to the system design device 80.

Here, in the system design device 80 according to the first and second example embodiments, the constraint condition generation unit 50 generates constraint conditions for a target system configuration generated by the system design unit 20 during system design. On the other hand, in the first and second example embodiments, there is no limitation on when the system design unit 20 provides the system configuration information to the constraint condition generation unit 50.

Concerning the timing at which the constraint condition generation unit 50 generates constraint conditions, a method of generating constraint conditions each time the concretization of a system configuration progresses by one step, that is, each time a concretization rule is applied, can be considered. According to this method, the system design device can detect system configurations that cannot satisfy constraint conditions at a relatively early stage of system design and exclude those system configurations from being concretized, which is expected to enable efficient system design.

On the other hand, in order to generate more accurate constraint conditions, it is considered desirable to advance the concretization of the system configuration to the point where a concrete operating system and machine are included in the system configuration. In the above method of generating constraint conditions each time the system configuration is concretized, if the system configuration is not yet concretized, the accuracy of the obtained constraint conditions may be relatively low, and in this respect, it is conceivable that the effectiveness of generating constraint conditions may be relatively low in some cases.

Regarding the timing of constraint condition generation by the constraint condition generation unit 50, it is also conceivable to generate constraint conditions if a concretized system configuration, which does not include abstract configuration components, is obtained for the target system configuration. In this method, the processing load imposed on the constraint condition generation unit 50 for generating constraint conditions can be made relatively low.

On the other hand, if a concretized system configuration, which does not include abstract configuration components, is obtained for the target system configuration, the method of generating constraint conditions cannot exclude system configurations that cannot satisfy the constraint conditions at an intermediate stage in the concretization of the system configuration.

In contrast, in the system design device 180, if the design state determination unit 90 detects that a pre-designated condition is satisfied, the constraint condition generation unit 50 generates a constraint condition. This makes it possible for the system design device 180 to designate the timing at which the constraint condition generation unit 50 generates constraint conditions. In this respect, it is possible to exclude system configurations that cannot satisfy the constraint conditions at a relatively early stage of system design, while reducing the number of times the constraint condition generation unit 50 generates constraint conditions.

The system design device 180 corresponds to a more specific example of the system design device 80 of the first example embodiment or the system design device 80 of the second example embodiment.

The design state determination unit 90 corresponds to an example of the design state determination means.

The design state determination unit 90 preliminarily stores information indicating the condition under which the constraint condition generation unit 50 generates constraint conditions. The information indicating the condition under which the constraint condition generation unit 50 generates constraint conditions can be described as information on what condition the system configuration being designed must satisfy before the system design unit 20 can pass system configuration information to the constraint condition generation unit 50.

The condition under which the constraint condition generation unit 50 generates constraint conditions is also referred to as a constraint generation condition.

The constraint generation condition is not limited to a particular condition. For example, the constraint generation condition may be a condition such that a machine is concretized within a system configuration being designed. Alternatively, the constraint generation condition may be a condition such that five concretization rules are applied additionally.

The design state determination unit 90 receives system configuration information from the system design unit 20, determines whether or not the constraint generation condition is satisfied, and returns the determination result to the system design unit 20.

Each time the system design unit 20 applies one concretization rule to a system configuration in the process of being designed, it passes information on the concretized system configuration to the design state determination unit 90. The system design unit 20 then receives a determination result from the design state determination unit 90 as to whether or not the constraint generation condition is satisfied.

If the system design unit 20 receives a determination result indicating the constraint generation condition being satisfied, the system design unit 20 passes the system configuration information to the constraint condition generation unit 50. The constraint condition generation unit 50 generates a constraint condition, using the received system configuration information.

On the other hand, if the system design unit 20 receives a determination result indicating the constraint generation condition not being satisfied, the system design unit 20 does not pass the system configuration information to the constraint condition generation unit 50, and continues the process of concretizing the system design.

### (Description of Operation)

Next, the operation of the system design device 180 according to the third example embodiment will be described. Here, it is assumed that a constraint generation condition is set to “a concretized machine node is present in the system configuration”, and the process flow will be described using examples in which the system design device 180 concretizes the system configurations shown in FIG. 23 to FIG. 28.

Every time the system design unit 20 applies one of the concretization rules to a system requirement or a system configuration, it passes the system configuration information at that time to the design state determination unit 90.

For example, the system design unit 20 applies the concretization rule 10 to the system requirement T1 to concretize it into the system configuration T2, and passes the configuration information of the system configuration T2 to the design state determination unit 90.

The design state determination unit 90 refers to the received system configuration T2 and determines whether or not a concretized machine node is present. Since no concretized machine node is present in the system configuration T2, the design state determination unit 90 returns to the system design unit 20 information indicating that the constraint generation condition is not satisfied.

The system design unit 20, which has received the notification that the constraint generation condition is not satisfied, further advances the concretization of the system configuration.

Thereafter, similarly, the system design unit 20 passes the system configuration information at that time to the design state determination unit 90 each time a concretization rule is applied, and the design state determination unit 90 determines whether or not the constraint generation condition is satisfied. In the concretization examples shown in FIG. 23 to FIG. 28, the system configuration T5 and previous system configurations do not include concretized machine nodes. Therefore, for the system configuration T5 and the system configurations before that, the design state determination unit 90 returns to the system design unit 20 a determination result that the constraint generation condition is not satisfied.

On the other hand, in the examples of FIG. 23 to FIG. 28, the system configuration T6 includes a Machine_Z2 node which is a concretized machine node. Therefore, the design state determination unit 90 returns to the system design unit 20 a determination result indicating that the constraint generation condition is satisfied for the system configuration T6.

The system design unit 20, which has received the determination result of the constraint generation condition being satisfied, passes the configuration information of the system configuration T6 to the constraint condition generation unit 50. Thereafter, each unit of the system design device 180 performs processing similar to that in the second example embodiment.

The system configuration T7, and all subsequent system configurations, now include the concretized machine node, Machine_Z2 node. Therefore, for the system configuration T7 and subsequent system configurations, each time the system design unit 20 applies a concretization rule to the system configuration, the constraint condition generation unit 50 generates a constraint condition, and thereafter, each unit of the system design device 180 performs processing in the same manner as that in the second example embodiment.

### (Description of Effect)

According to the system design device 180 of the third example embodiment, it is possible to arbitrarily specify the timing for generating a constraint condition for the system configuration being designed. In this respect, according to the system design device 180 of the third example embodiment, it is possible to efficiently determine whether or not to exclude system configurations that cannot satisfy the constraint condition during the design stage, thereby enabling efficient system design.

As described above, the design state determination unit 90 determines whether or not the target system configuration satisfies the preliminarily set candidate determination start condition. The constraint condition generation unit 50 generates a constraint condition if the design state determination unit 90 determines that the target system satisfies the candidate determination start condition. The constraint validation unit 30, if the constraint condition generation unit 50 generates a constraint condition, determines whether or not the target system configuration can satisfy the constraint condition.

As described above, according to the system design device 180, it is possible to arbitrarily designate the timing for generating constraint conditions for the system configuration being designed. In this respect, according to the system design device 180, it is possible to efficiently determine whether or not to exclude system configurations that cannot satisfy the constraint condition during the design stage, thereby enabling efficient system design.

### Fourth Example Embodiment

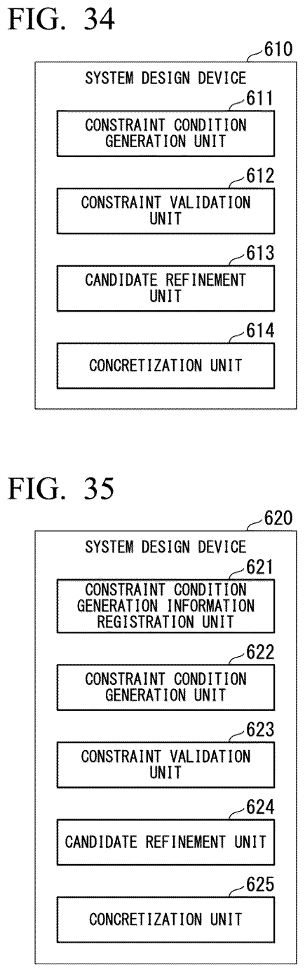

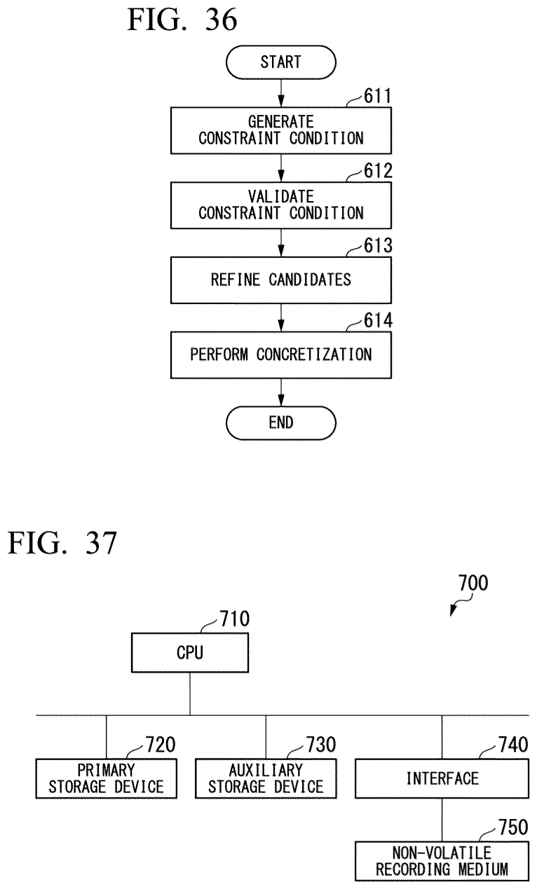

FIG. 34 is a block diagram showing a configuration example of a system design device according to a fourth example embodiment. In the configuration shown in FIG. 34, a system design device 610 includes a constraint condition generation unit 611, a constraint validation unit 612, a candidate refinement unit 613, and a concretization unit 614.

With such a configuration, the constraint condition generation unit 611 selects one or more of the configuration components of the target system configuration, based on the configuration component selection method indicated in the constraint condition generation information that is associated with system configuration information that indicates a target system configuration that is one of target candidates for system design performed through repetitive application of a concretization rule to the system configuration including abstract configuration components, and that indicates a method of generating constraint conditions for the target system configuration. Then, the constraint condition generation unit 611 generates a constraint condition for the target system configuration by applying a method of generating a constraint condition indicated in the system configuration information or the constraint condition generation information, to information set for configuration components selected.

The constraint validation unit 612 determines whether or not the target system configuration can satisfy the constraint conditions.

The candidate refinement unit 613 excludes the target system configurations from the target candidates for system design if the constraint validation unit 612 determines that the target system configurations cannot satisfy the constraint conditions.

The concretization unit 614 applies the concretization rules to the target candidates for system design to advance the system design.

The constraint condition generation unit 611 corresponds to an example of the constraint condition generation means. The constraint validation unit 612 corresponds to an example of the constraint validation means. The candidate refinement unit 613 corresponds to an example of the candidate refinement means. The concretization unit 614 corresponds to an example of the concretization means.

According to the system design device 610, it is possible to determine whether or not multiple configuration components satisfy constraint conditions, even for configuration components other than those whose relationships are directly indicated among the configuration components of the system configuration. According to the system design device 80, it is possible to exclude system configurations that cannot satisfy constraint conditions from candidates for system design, and in this respect, this enables efficient system design.

### Fifth Example Embodiment

FIG. 35 is a block diagram showing a configuration example of a system design device according to a fifth example embodiment. In the configuration shown in FIG. 35, a system design device 620 includes a constraint condition generation information registration unit 621, a constraint condition generation unit 622, a constraint validation unit 623, a candidate refinement unit 624, and a concretization unit 625.

With such a configuration, the constraint condition generation information registration unit 621 receives an input of constraint condition generation information indicating a method of generating a constraint condition that must be satisfied by a system configuration that is a candidate for system design performed through repetitive application of a concretization rule to a system configuration including abstract configuration components.

The constraint condition generation unit 622 generates a constraint condition that must be satisfied by a target system configuration, based on system configuration information that indicates a target system configuration that is one of the candidates for system design and the constraint condition generation information.

The constraint validation unit 623 determines whether or not the target system configuration can satisfy the constraint conditions.

The candidate refinement unit 624 excludes the target system configurations from the target candidates for system design if the constraint validation unit 623 determines that the target system configurations cannot satisfy the constraint conditions.

The concretization unit 625 applies the concretization rules to the target candidates for system design to advance the system design.

The constraint condition generation information registration unit 621 corresponds to an example of the constraint condition generation information registration means. The constraint condition generation unit 622 corresponds to an example of the constraint condition generation means. The constraint validation unit 623 corresponds to an example of the constraint validation means. The candidate refinement unit 624 corresponds to an example of the candidate refinement means. The concretization unit 625 corresponds to an example of the concretization means.

According to the system design device 620, the user can input desired constraint generation information from the constraint condition generation information registration unit 621. In this respect, according to the system design device 620, it is possible to design a system that satisfies the conditions desired by the user.

Moreover, according to the system design device 620, based on the constraint condition generation information input from the constraint condition generation information registration unit 621, it is possible to determine whether or not multiple configuration components satisfy constraint conditions, even for configuration components other than those whose relationships are directly indicated among the configuration components of the system configuration. According to the system design device 80, it is possible to exclude system configurations that cannot satisfy constraint conditions from candidates for system design, and in this respect, this enables efficient system design.

### Sixth Example Embodiment

FIG. 36 is a diagram showing an example of a processing procedure in a system design method according to a sixth example embodiment. The method shown in FIG. 36 includes generating a constraint condition (Step S611), validating whether or not the constraint condition is satisfied (Step S612), refining candidates (Step S613), and concretizing (Step S614).

In generating a constraint condition (Step S611), one or more of configuration components of a target system configuration are selected based on a configuration component selection method indicated in constraint condition generation information that is associated with system configuration information, the system configuration information indicating a target system configuration, the target system configuration being one of target candidates for system design in which repetitive application of a concretization rule to a system configuration including an abstract configuration component is performed, the constraint condition generation information indicating a method of generating a constraint condition for the target system configuration, and a constraint condition for the target system configuration is generated by applying the method of generating the constraint condition indicated in the system configuration information or the constraint condition generation information.

In validating whether or not the constraint condition is satisfied (Step S612), it is determined whether or not the target system configuration can satisfy the constraint conditions.

In refining candidates (Step S613), the target system configuration is excluded from the target candidates for system design if it is determined that the target system configuration cannot satisfy the constraint condition.

In concretizing (Step S614), the concretization rules are applied to the target candidates for system design to advance the system design.

According to the system design method shown in FIG. 36, it is possible to determine whether or not multiple configuration components satisfy constraint conditions, even for configuration components other than those whose relationships are directly indicated among the configuration components of the system configuration. According to the system design method shown in FIG. 36, it is possible to exclude system configurations that cannot satisfy constraint conditions from candidates for system design, and in this respect, this enables efficient system design.

FIG. 37 is a schematic block diagram showing a configuration of a computer according to at least one of the example embodiments.

In the configuration shown in FIG. 37, a computer 700 includes a CPU (Central Processing Unit) 710, a primary storage device 720, an auxiliary storage device 730, and an interface 740.

One or more of the system design devices 80, 180, 610, and 620 or part thereof may be implemented in the computer 700. In such a case, operations of the respective processing units described above are stored in the auxiliary storage device 730 in the form of a program. The CPU 710 reads out the program from the auxiliary storage device 730, loads it on the primary storage device 720, and executes the processing described above according to the program. Moreover, the CPU 710 reserves, according to the program, storage regions corresponding to the respective storage units mentioned above, in the primary storage device 720. Communication between each device and other devices is executed by the interface 740 having a communication function and communicating under the control of the CPU 710.

In a case where the system design device 80 is implemented in the computer 700, the input/output unit 10, the system design unit 20, the constraint validation unit 30, the design information recording unit 40, the constraint condition generation unit 50, the constraint function recording unit 60, the constraint function registration unit 70, and the operations of these units are stored in the form of programs in the auxiliary storage device 730. The CPU 710 reads out the programs from the auxiliary storage device 730, loads them on the primary storage device 720, and executes the processes described above, according to the programs.

Moreover, the CPU 710 reserves a storage region in the primary storage device 720 for the processing of the system design device 80, such as a storage region for the design information recording unit 40 and the constraint function recording unit 60, in accordance with the programs. Communication between the system design device 80 and other devices is executed by the interface 740 having a communication function and communicating under the control of the CPU 710. Interactions between the system design device 80 and the user, such as the acceptance of the registration of constraint functions by the constraint function registration unit 70, are executed by the interface 740, which includes a display device and an input device, displaying various images under the control of the CPU 710 and receiving user operations.

In a case where the system design device 180 is implemented in the computer 700, the input/output unit 10, the system design unit 20, the constraint validation unit 30, the design information recording unit 40, the constraint condition generation unit 50, the constraint function recording unit 60, the constraint function registration unit 70, the design state determination unit 90, and the operations of these units are stored in the form of programs in the auxiliary storage device 730. The CPU 710 reads out the programs from the auxiliary storage device 730, loads them on the primary storage device 720, and executes the processes described above, according to the programs.

Moreover, the CPU 710 reserves a storage region in the primary storage device 720 for the processing of the system design device 180, such as a storage region for the design information recording unit 40 and the constraint function recording unit 60, in accordance with the programs. Communication between the system design device 180 and other devices is executed by the interface 740 having a communication function and communicating under the control of the CPU 710. Interactions between the system design device 180 and the user, such as the acceptance of the registration of constraint functions by the constraint function registration unit 70, are executed by the interface 740, which includes a display device and an input device, displaying various images under the control of the CPU 710 and receiving user operations.

In a case where the system design device 610 is implemented in the computer 700, the operations of the constraint condition generation unit 611, the constraint validation unit 612, the candidate refinement unit 613, and the concretization unit 614 are stored in the auxiliary storage device 730 in the form of programs. The CPU 710 reads out the programs from the auxiliary storage device 730, loads them on the primary storage device 720, and executes the processes described above, according to the programs.

Also, the CPU 710 reserves a storage region in the primary storage device 720 for the processing to be performed by the system design device 610, according to the programs. Communication between the system design device 610 and other devices is executed by the interface 740 having a communication function and communicating under the control of the CPU 710. Interaction between the system design device 610 and the user is executed by the interface 740 having a display device and an input device, displaying various images under control of the CPU 710, and receiving user operations.

In a case where the system design device 620 is implemented in the computer 700, the operations of the constraint condition generation information registration unit 621, the constraint condition generation unit 622, the constraint validation unit 623, the candidate refinement unit 624, and the concretization unit 625 are stored in the auxiliary storage device 730 in the form of programs. The CPU 710 reads out the programs from the auxiliary storage device 730, loads them on the primary storage device 720, and executes the processes described above, according to the programs.

Also, the CPU 710 reserves a storage region in the primary storage device 720 for the processing to be performed by the system design device 620, according to the programs. Communication between the system design device 620 and other devices is executed by the interface 740 having a communication function and communicating under the control of the CPU 710. Interaction between the system design device 620 and the user is executed by the interface 740 having a display device and an input device, displaying various images under control of the CPU 710, and receiving user operations.

It should be noted that a program for executing some or all of the processes performed by the system design device 80, 180, 610, and 620 may be recorded on a computer-readable recording medium, and the program recorded on the recording medium may be read into and executed on a computer system, to thereby perform the processing of each unit. The “computer system” here includes an OS (operating system) and hardware such as peripheral devices.

Moreover, the “computer-readable recording medium” referred to here refers to a portable medium such as a flexible disk, a magnetic optical disk, a ROM (Read Only Memory), and a CD-ROM (Compact Disc Read Only Memory), or a storage device such as a hard disk built in a computer system. The above program may be a program for realizing a part of the functions described above, and may be a program capable of realizing the functions described above in combination with a program already recorded in a computer system.

The example embodiments of the present invention have been described in detail with reference to the drawings. However, the specific configuration of the invention is not limited to the example embodiments, and may include designs and so forth that do not depart from the scope of the present invention.

The whole or part of the example embodiments disclosed above can be described as, but not limited to, the following supplementary notes.

### (Supplementary Note 1)

A system design device comprising:
a constraint condition generation means that selects one or more of configuration components of a target system configuration based on a configuration component selection method indicated in constraint condition generation information that is associated with system configuration information, wherein the system configuration information indicates a target system configuration, the target system configuration is one of target candidates for system design in which repetitive application of a concretization rule to a system configuration including an abstract configuration component is performed, the constraint condition generation information indicates a method of generating a constraint condition for the target system configuration, the constraint condition generation means generating a constraint condition for the target system configuration by applying the method of generating the constraint condition indicated in the system configuration information or the constraint condition generation information;
a constraint validation means that determines whether or not the target system configuration can satisfy the constraint condition;
a candidate refinement means that excludes the target system configuration from the target candidates for system design if the constraint validation means determines that the target system configuration cannot satisfy the constraint condition; and
a concretization means that advances the system design by applying the concretization rule to the target candidates for the system design.

### (Supplementary Note 2)

The system design device according to supplementary note 1, further comprising
a constraint condition generation information storage means that stores the constraint condition generation information,
wherein the constraint condition generation information includes constraint condition generation information identification information for identifying the constraint condition generation information itself, and
the system configuration information with which the constraint condition generation information is associated includes constraint condition generation information identification information for identifying the associated constraint condition generation information.

### (Supplementary Note 3)

The system design device according to supplementary note 2, further comprising a constraint condition generation information registration means that receives an input of new constraint condition generation information and stores the constraint condition generation information having been input into the constraint condition generation information storage means.

### (Supplementary Note 4)

The system design device according to any one of supplementary notes 1 to 3, wherein the system configuration information includes a model indicating a configuration of a process executed by the system configuration, and the constraint condition generation means generates a constraint condition related to the process, based on a model indicating a configuration of the process.

### (Supplementary Note 5)

The system design device according to supplementary note 4,
wherein the system configuration information includes information on a processing time for each process, and
the constraint condition generation means extracts, based on a process extraction method indicated in the constraint condition generation information, a process group constituting a series of processing executed by a predetermined process call designated in the system configuration information, and generates a constraint condition such that a total processing time of each process included in the process group extracted is within an allowable time range designated for the process call.

### (Supplementary Note 6)

The system design device according to supplementary note 4,
wherein the system configuration information includes information on a computational resource usage for each process, and
the constraint condition generation means extracts, based on a process extraction method indicated in the constraint condition generation information, a process group that utilizes a predetermined computational resource indicated in the system configuration information, and generates a constraint condition such that a total amount of computational resources required for each process included in the extracted process group to perform processing in a service time and at a processing request arrival rate designated for that process, for the process group, is within a range of an amount of computational resources that is capable of being provided by the computational resources.

### (Supplementary Note 7)

The system design device according to any one of supplementary notes 1 to 6, further comprising
a design state determination means that determines whether or not the target system configuration satisfies a candidate determination start condition that is set preliminarily,
wherein the constraint condition generation means generates the constraint condition if the design state determination means determines that the target system satisfies the candidate determination start condition, and
the constraint validation means determines whether or not the target system configuration can satisfy the constraint condition if the constraint condition generation means generates the constraint condition.

### (Supplementary Note 8)

A system design device comprising:
a constraint condition generation information registration means that receives an input of constraint condition generation information indicating a method of generating a constraint condition that must be satisfied by a system configuration that is a candidate for system design in which repetitive application of a concretization rule to a system configuration including an abstract configuration component;
a constraint condition generation means that generates a constraint condition that must be satisfied by a target system configuration, based on system configuration information that indicates the target system configuration that is one of the target candidates for system design and the constraint condition generation information;
a constraint validation means that determines whether or not the target system configuration can satisfy the constraint condition;
a candidate refinement means that excludes the target system configuration from the target candidates for the system design if the constraint validation means determines that the target system configuration cannot satisfy the constraint condition; and
a concretization means that advances the system design by applying the concretization rule to the target candidates for the system design.

### (Supplementary Note 9)

A system design method comprising:
selecting one or more of configuration components of a target system configuration based on a configuration component selection method indicated in constraint condition generation information that is associated with system configuration information, wherein the system configuration information indicates a target system configuration, the target system configuration is one of target candidates for system design in which repetitive application of a concretization rule to a system configuration including an abstract configuration component is performed, the constraint condition generation information indicates a method of generating a constraint condition for the target system configuration, generating a constraint condition for the target system configuration by applying the method of generating the constraint condition indicated in the system configuration information or the constraint condition generation information;
determining whether or not the target system configuration can satisfy the constraint condition;
excluding the target system configuration from the target candidates for system design if it is determined that the target system configuration cannot satisfy the constraint condition; and
advancing the system design by applying the concretization rule to the target candidates for the system design.

### (Supplementary Note 10)

A recording medium having recorded therein a program causing a computer to execute:
selecting one or more of configuration components of a target system configuration based on a configuration component selection method indicated in constraint condition generation information that is associated with system configuration information, wherein the system configuration information indicates a target system configuration, the target system configuration is one of target candidates for system design in which repetitive application of a concretization rule to a system configuration including an abstract configuration component is performed, the constraint condition generation information indicates a method of generating a constraint condition for the target system configuration, generating a constraint condition for the target system configuration by applying the method of generating the constraint condition indicated in the system configuration information or the constraint condition generation information;
determining whether or not the target system configuration can satisfy the constraint condition;
excluding the target system configuration from the target candidates for system design if it is determined that the target system configuration cannot satisfy the constraint condition; and
advancing the system design by applying the concretization rule to the target candidates for the system design.

### (Supplementary Note 11)

The recording medium according to supplementary note 10, wherein the constraint condition generation information is programmed as a function including: a module that selects one or more configuration components of the target system configuration by executing a configuration component selection method; and a module that generates a constraint condition for the target system configuration by applying a method of generating a constraint condition indicated in the system configuration information or the constraint condition generation information, to information set for the selected configuration component.

### INDUSTRIAL APPLICABILITY

The present invention may be applied to a system design device, a system design method, and a recording medium.

### DESCRIPTION OF REFERENCE SYMBOLS

10 Input/output unit
20 System design unit
21, 613, 624 Candidate refinement unit
22, 614, 625 Concretization unit
30, 612, 623 Constraint validation unit
40 Design information recording unit
50, 611, 622 Constraint condition generation unit
60 Constraint Function recording unit
70 Constraint function registration unit
80, 180, 610, 620 System design device
90 Design state determination unit

What is claimed is:

1. A system design device comprising:
a memory configured to store instructions; and
a processor configured to execute the instructions to:
select one or more of configuration components of a target system configuration based on a configuration component selection method indicated in constraint condition generation information that is associated with system configuration information, wherein the system configuration information indicates a target system configuration, the target system configuration is one of target candidates for system design in which repetitive application of a concretization rule to a system configuration including an abstract configuration component is performed, the constraint condition generation information indicates a method of generating a constraint condition for the target system configuration;
generate a constraint condition for the target system configuration based on information set for the selected configuration component and the method of generating the constraint condition indicated in the concretization rule or the constraint condition generation information;
determine whether or not the target system configuration can satisfy the constraint condition;
exclude the target system configuration from the target candidates for system design if it is determined that the target system configuration cannot satisfy the constraint condition; and
advance the system design by applying the concretization rule to the target candidates for the system design.

2. The system design device according to claim 1,
wherein the memory stores the constraint condition generation information,
the constraint condition generation information includes constraint condition generation information identification information for identifying the constraint condition generation information itself, and
the system configuration information with which the constraint condition generation information is associated includes constraint condition generation information identification information for identifying the associated constraint condition generation information.

3. The system design device according to claim 2, wherein the processor is configured to execute the instructions to receive an input of new constraint condition generation information and store the constraint condition generation information having been input into the memory.

4. The system design device according to claim 1,
wherein the system configuration information includes a model indicating a configuration of a process executed by the system configuration, and
the processor is configured to execute the instructions to generate a constraint condition related to the process, based on a model indicating a configuration of the process.

5. The system design device according to claim 4,
wherein the system configuration information includes information on a processing time for each process, and
the processor is configured to execute the instructions to extract, based on a process extraction method indicated in the constraint condition generation information, a process group constituting a series of processing executed by a predetermined process call designated in the system configuration information, and generate a constraint condition such that a total processing time of each process included in the process group extracted is within an allowable time range designated for the process call.

6. The system design device according to claim 4,
wherein the system configuration information includes information on a computational resource usage for each process, and
the processor is configured to execute the instructions to extract, based on a process extraction method indicated in the constraint condition generation information, a process group that utilizes a predetermined computational resource indicated in the system configuration information, and generate a constraint condition such that a total amount of computational resources required for each process included in the extracted process group to perform processing in a service time and at a processing request arrival rate designated for that process, for the process group, is within a range of an amount of computational resources that is capable of being provided by the computational resources.

7. The system design device according to claim 1,
wherein the processor is configured to execute the instructions to determine whether or not the target system configuration satisfies a candidate determination start condition that is set preliminarily,
the processor is configured to execute the instructions to generate the constraint condition if it is determined that the target system configuration satisfies the candidate determination start condition, and
the processor is configured to execute the instructions to determine whether or not the target system configuration can satisfy the constraint condition if the constraint condition is generated.

8. A system design device comprising:
a memory configured to store instructions; and
a processor configured to execute the instructions to:
receive an input of constraint condition generation information indicating a method of generating a constraint condition that must be satisfied by a system configuration that is a candidate for system design in which repetitive application of a concretization rule to a system configuration including an abstract configuration component;
generate a constraint condition that must be satisfied by a target system configuration, based on system configuration information that indicates the target system configuration that is one of the target candidates for system design and the constraint condition generation information;
determine whether or not the target system configuration can satisfy the constraint condition;
exclude the target system configuration from the target candidates for the system design if it is determined that the target system configuration cannot satisfy the constraint condition; and
advance the system design by applying the concretization rule to the target candidates for the system design.

9. A system design method comprising:
selecting one or more of configuration components of a target system configuration based on a configuration component selection method indicated in constraint condition generation information that is associated with system configuration information, wherein the system configuration information indicates a target system configuration, the target system configuration is one of target candidates for system design in which repetitive application of a concretization rule to a system configuration including an abstract configuration component is performed, the constraint condition generation information indicates a method of generating a constraint condition for the target system configuration;
generating a constraint condition for the target system configuration based on information set for the selected configuration component and the method of generating the constraint condition indicated in the concretization rule or the constraint condition generation information;
determining whether or not the target system configuration can satisfy the constraint condition;
excluding the target system configuration from the target candidates for system design if it is determined that the target system configuration cannot satisfy the constraint condition; and
advancing the system design by applying the concretization rule to the target candidates for the system design.

10.-11. (canceled)
